(19) United States
(12) Patent Application Publication
(10) Pub. No.: US 2007/0132011 A1
(43) Pub. Date: Jun. 14, 2007

(54) Semiconductor device and method of fabricating the same background

(75) Inventor: Juri Kato, Chino-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Tokyo (JP)

(21) Appl. No.: 11/635,831

(22) Filed: Dec. 8, 2006

(30) Foreign Application Priority Data
Dec. 9, 2005 (JP) 2005-355984
Dec. 15, 2005 (JP) 2005-361728
Sep. 19, 2006 (JP) 2006-252586

(51) Int. Cl. H01L 29/792

(52) U.S. Cl. 257/324

(57) ABSTRACT

A semiconductor device includes a semiconductor layer formed on a semiconductor substrate by epitaxial growth, a first embedded insulating layer embedded in a first region between the semiconductor substrate and the substrate layer, and a second embedded insulating layer embedded in a second region between the semiconductor substrate and the semiconductor layer, wherein the first embedded insulating layer and the second embedded insulating layer are mutually different in at least either of effective work function and fixed charge amount.

### BACKGROUND

1. Technical Field

The present invention relates to a semiconductor device and a method of manufacturing the same, particularly to a semiconductor device that is preferably applied to a semiconductor device having an embedded insulating layer formed on the back of an silicon on insulator (SOI) transistor.

2. Related Art

Much attention has been paid to the utility of a field effect transistor formed on an SOI substrate in view of its ease of element isolation, being latchup-free, small source/drain joint capacitance, and the like.

In JP-A-1998-261799, for example, disclosed is a method of forming a silicon thin film having excellent crystallinity and uniformity on an insulating film with a large area, by irradiating an ultraviolet beam to an amorphous or polycrystalline silicon layer formed on an insulating film in a pulse-shape to form a polycrystalline silicon film, in which single crystal particles shaped in nearly a square are arranged in a lattice pattern, on the insulating film, and then by planarizing the surface of the polycrystalline silicon film by chemical mechanical polishing (CMP).

However, the silicon thin film formed on the insulating film has grain boundaries, microtwins, and other various minute faults. This has resulted in a problem that a field effect transistor formed in such a silicon thin film is inferior in transistor characteristic to a field effect transistor formed in a perfect single-crystal silicon.

When the field effect transistor formed in the silicon thin film is laminated, the field effect transistor exists in a lower layer. This has caused a problem that flatness of a base insulating film, in which an upper layer silicon thin film is formed, is deteriorated. This has also caused a problem that due to a limitation imposed on the thermal treatment conditions and the like at the time of forming the upper silicon thin film, the upper layer silicon thin film is inferior in crystallinity to the lower layer silicon thin film.

In the conventional semiconductor integrated circuits, the rise characteristic of the drain current in the subthreshold region is deteriorated when the channel length is shortened as the transistor is miniaturized. This has prevented low-voltage operation of the transistor, increased the off-leak current, and increased operating and standby power consumption. This has also caused thermal destruction to the transistor. In order to control the threshold and suppress short channel effects by punch through, the impurity concentration of the SOI layer body may be increased, and the SOI layer in the channel region may be made thinner. Alternatively, in order to obtain a steep subthreshold characteristic, the SOI layer in the channel region may be made thinner. Both the thinned SOI and the increased impurity concentration of the SOI layer body have increased variations in transistor characteristic as well as lowered carrier mobility, thus reducing the on-current of the transistor.

### SUMMARY

An advantage of the present invention is to provide a semiconductor and a method of manufacturing the same that can suppress deterioration of crystallinity of a semiconductor layer having a field effect transistor formed therein, prevent deterioration of the carrier mobility regardless of whether the threshold voltage is high or low, and achieve a stable transistor characteristic, or can improve dynamic threshold controllability by a back gate electrode.

A semiconductor device according to a first aspect of the invention includes a semiconductor layer formed on a semiconductor substrate by epitaxial growth, a first embedded insulating layer embedded in a first region between the semiconductor substrate and the substrate layer, and a second embedded insulating layer embedded in a second region between the semiconductor substrate and the semiconductor layer, wherein the first embedded insulating layer and the second embedded insulating layer are mutually different in at least either one of effective work function and fixed charge amount.

According to this aspect, even when the body region of the semiconductor layer is doped intrinsically or in a low concentration, it is possible to mix field effect transistors with different threshold voltages on the same substrate. Since it is possible to lower the dopant concentration of the semiconductor layer regardless of whether the threshold voltage is high or low, even when field effect transistors with different threshold voltages are mixed on the same substrate, it is possible to improve the carrier mobility of all the mixed field effect transistors and thus to increase the on-current. Further, since it is possible to lower the impurity concentration of the substrate layer insofar as the short channel effect is suppressed, it is made possible to obtain a steep subthreshold characteristic even when the substrate layer is made thicker. Thus, it is made possible to reduce variations in transistor characteristics while optimizing the threshold voltage for each of the mixed field effect transistors as well as to improve the manufacturing yield, reducing the cost.

In the semiconductor device according to this aspect, the first embedded insulating layer or the second the embedded insulating layer preferably consists of a silicon nitride film, a silicon oxide film containing Al, Hf oxide containing Al, Zr oxide containing Al, a silicon oxide film not containing Al, Hf oxide not containing Al, or Zr oxide not containing Al.

For example, the first embedded insulating layer may consist of a silicon nitride film, a silicon oxide film containing Al, Hf oxide containing Al, or Zr oxide containing Al, and the second embedded insulating layer may consist of a silicon oxide film not containing Al, Hf oxide not containing Al, or Zr oxide not containing Al.

As a result, it is made possible to reduce the interface state density while maintaining flatness of the interface between a gate insulating layer and a channel on the surface of the semiconductor layer. It is also made possible to mix field effect transistors with plural and different threshold voltages while keeping the impurity concentration of the semiconductor layer in the channel region at a low level. This makes it possible to suppress deterioration of carrier mobility, to suppress variations in transistor characteristic, and to achieve a steep subthreshold characteristic. Thus, it is made possible to speed up the field effect transistor while reducing operating power consumption.

A semiconductor device according to a second aspect of the invention includes a semiconductor layer formed on a first insulating layer and a second insulating layer, a first back gate electrode disposed below the semiconductor layer via the first insulating layer, a second back gate electrode disposed below the semiconductor layer via the second insulating layer, a first gate electrode formed on the semiconductor layer on the first insulating layer, and a second gate electrode formed on the semiconductor layer on the second insulating layer, wherein the first and second insulating layers are mutually different in at least either one of effective work function and fixed charge amount.

In this case, the first and second back gate electrodes may consist of an identical material or different materials having different work functions. Further, the first and second gate electrodes may consist of an identical material or different materials having different work functions.

Consequently, it is made possible to control the potential of the active region of the field effect transistor at the back gate electrode without being limited by the disposition of the gate electrode, source/drain contacts, or the like. This makes it possible to control complication of the manufacturing process as well as to dynamically control the threshold voltage of the field effect transistor. Further, when the back gate electrode and the gate electrode of the field effect transistor are connected, it is made possible to improve the rise characteristic of the drain current in the subthreshold region as well as to alleviate the electric field at the channel end on the drain side. This makes it possible to reduce the off-leak current and to reduce operating and standby power consumption while making the transistor operate at low voltage, as well as to make the field effect transistor highly voltage resistant.

Further, by setting the first and second insulating layers so as to be mutually different in at least either one of effective work function and fixed charge amount, it is made possible to mix field effect transistors with different threshold voltages on the same substrate even when the body region of the semiconductor layer is doped intrinsically or in a low concentration and fixed. This makes it possible to lower the dopant concentration of the semiconductor layer regardless of whether the threshold voltage is high or low. Therefore, even when field effect transistors with different threshold voltages are mixed on the same substrate, it is possible to improve carrier mobility of the field effect transistors and to increase the on-current of all the mixed transistors. Since it is possible to lower the impurity concentration of the semiconductor layer, it is made possible to obtain a steep subthreshold characteristic even when the semiconductor layer is made thicker insofar as the short channel effect is suppressed. Therefore, it is made possible to reduce variations in transistor characteristics while optimizing the threshold voltage for each of the field effect transistors as well as to improve the manufacturing yield, reducing the cost.

According to this aspect of the invention, the first or second insulating layer preferably consist of a silicon nitride film, a silicon oxide film containing Al, Hf oxide containing Al, Zr oxide containing Al, a silicon oxide film not containing Al, Hf oxide not containing Al, or Zr oxide not containing Al.

For example, the first insulating layer may consist of a silicon nitride film, a silicon oxide film containing Al, Hf oxide containing Al, or Zr oxide containing Al, and the second insulating layer may consist of a silicon oxide film not containing Al, Hf oxide not containing Al, or Zr oxide not containing Al.

As a result, even when the gate film and the gate electrode of the field effect transistor are formed of an identical material and the concentration of the semiconductor layer body of the field effect transistor is constant, field effect transistors with different threshold voltages can be formed on the first insulating film and the second insulating film. Further, it is possible to dynamically control the respective threshold voltages of the field effect transistors at a low voltage via the back gate electrode on an individual basis.

According to this aspect of the invention, a wiring layer is preferably provided which electrically connects the first and second gate electrodes to the first and second back gate electrodes, respectively.

As a result, it is made possible to perform control so that the back side of the channel region of the field effect transistor has the same potential as the gate electrode and thus to improve control over the potential of the channel region. Therefore, even when the semiconductor layer is made thicker, it is made possible to obtain a steep subthreshold characteristic, as well as to reduce variations in transistor characteristics while reducing the off-leak current.

A method of manufacturing a semiconductor device according to a third aspect of the invention includes forming a first semiconductor layer on a semiconductor substrate, forming a second semiconductor layer, which has a smaller etching rate than the first semiconductor layer, on the first semiconductor layer, forming a first exposing section groove that exposes the semiconductor substrate by penetrating the first and second semiconductor layers and divides the first and second semiconductor layers into first and second regions, forming a supporter that supports the second semiconductor layer above the semiconductor substrate via the first exposing section, forming a second exposing section groove that exposes a part of the first semiconductor layer in the first region from the second semiconductor layer, forming below the second semiconductor layer a first cavity, in which the first semiconductor layer in the first region is eliminated, by selectively etching the first semiconductor layer in the first region via the second exposing section, forming a first embedded insulating layer in the first cavity, forming a third exposing section that exposes a part of the first semiconductor layer in the second region from the second semiconductor layer, forming below the second semiconductor layer a second cavity, in which the first semiconductor layer in the second region is eliminated, by selectively etching the first semiconductor layer in the second region via the third exposing section, and forming a second embedded insulating layer in the second cavity, wherein the first and second embedded insulating layers are mutually different in at least either one of effective work function and fixed charge amount.

Consequently, even when the second semiconductor layer is laminated on the first semiconductor layer, it is made possible to let an etching gas or etching liquid make contact with the first semiconductor layer via the second exposing section. Therefore, it is made possible to eliminate the first semiconductor layer by using a difference in etching rate between the first and second semiconductor layers while leaving the second semiconductor layer, as well as to form an embedded insulating layer in a cavity below the second semiconductor layer. Further, by forming a supporter that supports the second semiconductor layer above the semiconductor substrate, it is made possible to prevent the second semiconductor layer from falling on the semiconductor substrate even when a cavity is formed below the second semiconductor layer. Furthermore, by setting the first and second embedded insulating layers to be mutually different in at least either one of effective work function and fixed charge amount, it is made possible to mix field effect transistors with different threshold voltages on the same substrate even when the body region of the second semiconductor layer is doped intrinsically or in a low concentration. Therefore, it is made possible to form a plurality of SOI transistors with different threshold voltages on the second semiconductor layer without using any SOI substrate.

A method of manufacturing a semiconductor device according to a fourth aspect of the invention includes forming a first semiconductor layer on a semiconductor substrate, forming a second semiconductor layer, which has a smaller etching rate than the first semiconductor layer, on the first semiconductor layer, forming a third semiconductor layer, which has the same composition as the first semiconductor layer, on the second semiconductor layer, forming a fourth semiconductor layer, which has the same composition as the second semiconductor layer, on the third semiconductor layer, forming a first exposing section that exposes the semiconductor substrate by penetrating the first to fourth semiconductor layers and divides the first to fourth semiconductor layers into first and second regions, forming a supporter that supports the second and fourth semiconductor layers above the semiconductor substrate via the first exposing section, forming a second exposing section that exposes at least parts of the first and third semiconductor layers in the first region from the second and fourth semiconductor layers, forming first and second cavities, in which the first and third semiconductor layers in the first region are respectively eliminated, by selectively etching the first and third semiconductor layers via the second exposing section, forming a first embedded insulating layer in such a manner that the first embedded insulating layer is embedded in each of the first and second cavities, forming a third exposing section that exposes at least parts of the first and third semiconductor layers in the second region from the second and fourth semiconductor layers, forming third and fourth cavities, in which the first and third semiconductor layers in the second region are respectively eliminated, by selectively etching the first and third semiconductor layers via the third exposing section, and forming a second embedded insulating layer in each of the third and fourth cavities, wherein the first and second embedded insulating layers are mutually different in at least either one of effective work function and fixed charge amount.

Consequently, even when the second and fourth semiconductor layers are laminated on the first and third semiconductor layers, respectively, it is made possible to let an etching gas or etching liquid make contact with the first and third semiconductor layers via the second exposing section. Therefore, it is made possible to eliminate the first and third semiconductor layers while leaving the second and fourth semiconductor layers, as well as to form an embedded insulating layer in each of the first and second cavities below the second and fourth semiconductor layers, respectively. Further, by forming a supporter in such a manner that the supporter is embedded in the first exposing section, it is made possible to support the second and fourth semiconductor layers on the semiconductor substrate even when the first and second cavities are formed below the second and fourth semiconductor layers, respectively.

Therefore, it is made possible to dispose the second and fourth semiconductor layers on the embedded insulating layer while reducing occurrence of faults in the second and fourth semiconductor layers. Accordingly, it is made possible to form an SOI transistor in the fourth semiconductor layer without using any SOI substrate, as well as to dispose a back gate electrode consisting of the second semiconductor layer below the SOI transistor.

Further, by setting the first and second embedded insulating layers to be mutually different in at least either one of effective work function and fixed charge amount, it is made possible to mix field effect transistors with different threshold voltages on the same substrate even when the body region of the fourth semiconductor layer is doped intrinsically or in a low concentration, as well as to make a change to the threshold voltage of each field effect transistor. This makes it possible to lower the dopant concentration of the fourth semiconductor layer regardless of whether the threshold voltage is high or low. Therefore, even when transistors with different threshold voltages are mixed on the same substrate, it is made possible to improve the carrier mobility of the field effect transistors as well as to increase the on-current.

The method of manufacturing a semiconductor device according to the fourth aspect of the invention preferably further includes cleaning the respective backs of the second and fourth semiconductor layers with an ammonia-hydrogen peroxide solution including Al before forming the first or second embedded insulating layer.

Consequently, it is made possible to make the embedded insulating layer have a negative fixed charge, as well as to make a change to the threshold voltage of the field effect transistor by several volts even when the body region of the semiconductor layer is doped intrinsically or in a low concentration.

The method of manufacturing a semiconductor device according to the fourth aspect of the invention preferably further includes cleaning the respective backs of the second and fourth semiconductor layers with a hydrofluoric acid including Al before forming the first or second embedded insulating layer.

Consequently, it is made possible to make the embedded insulating layer have a positive fixed charge, as well as to make a change to the threshold voltage of the field effect transistor by several volts even when the body region of the semiconductor layer is doped intrinsically or in a low concentration.

In the method of manufacturing a semiconductor device according to the fourth aspect of the invention, the semiconductor substrate and the second and fourth semiconductor layers each consist of single-crystal Si, and the first and third semiconductor layers each consist of single-crystal SiGe.

Consequently, it is made possible to obtain a lattice match between the semiconductor substrate and the first to fourth semiconductor layers, as well as to make the etching rates of the first and third semiconductor layers larger than those of the semiconductor substrate and the second and fourth semiconductor layers. Therefore, it is made possible to form the second and fourth semiconductor layers, which have good crystal quality, on the first and third semiconductor layers, respectively, and thus to achieve insulation between the second and fourth semiconductor layers and the semiconductor substrate without losing the quality of the second and fourth semiconductor layers.

To solve the above mentioned problem, a semiconductor device according to a fifth aspect of the invention includes a semiconductor layer formed on a semiconductor substrate by epitaxial growth, an embedded insulating layer that is embedded between the semiconductor substrate and the semiconductor layer, a gate electrode formed on the semiconductor layer via a gate insulating film, and source/drain layers formed in the semiconductor layer and each disposed on a side of the gate electrode, wherein the embedded insulating layer and the gate insulating film are mutually different in at least either one of effective work function and fixed charge amount.

Consequently, it is made possible to make a change to the threshold voltage of the field effect transistor by several volts even when the body region of the semiconductor layer is doped intrinsically or in a low concentration. Therefore, it is made possible to lower the dopant concentration of the semiconductor layer regardless of whether the threshold voltage is high or low, to improve the carrier mobility of the field effect transistor, and to increase the on-current. Since it is made possible to lower the impurity concentration of the semiconductor layer, it is made possible to obtain a steep subthreshold characteristic even when the semiconductor layer is made thicker insofar as the short channel effect is suppressed. Therefore, it is possible to reduce variations in transistor characteristics as well as to improve the manufacturing yield, reducing the cost.

In the semiconductor device according to the fifth aspect of the invention, the gate insulating film and the embedded insulating layer are preferably mutually different in at least either one of effective work function and fixed charge amount. Further, the gate insulating film and the embedded insulating layer each preferably consist of a silicon oxide film, a silicon oxide nitride film, a silicon nitride film, a silicon oxide film containing Al, Hf oxide or HfSi oxide that contains Al or Y, Zr oxide or ZrSi oxide that contains Al or Y, Hf oxide or HfSi oxide that contains no Al nor Y, or Zr oxide or ZrSi oxide that contains no Al nor Y.

For example, when the gate insulating layer consists a silicon oxide film or a silicon oxide nitride film, and the embedded insulating layer consists of a silicon nitride film, a silicon oxide film containing Al, Hf oxide containing Al, Zr oxide containing Al, Hf oxide not containing Al, or Zr oxide not containing Al, it is made possible to reduce the interface state density while ensuring flatness of the interface between the gate insulating film and the channel. It is also made possible to control the threshold voltage of the field effect transistor while keeping the impurity concentration at a low level even when the semiconductor layer in the channel region is made thinner. Therefore, it is made possible to suppress deterioration of the carrier mobility and to let the transistor operate at a low voltage, as well as to obtain a steep subthreshold characteristic while suppressing variations in transistor characteristics. This makes it possible to speed up the field effect transistor while reducing the operating power consumption.

A semiconductor device according to a sixth aspect of the invention includes a semiconductor layer formed on an insulating layer, a back gate electrode disposed below the semiconductor layer via the insulating layer, a gate electrode formed on the semiconductor layer, and gate/drain layers formed in the semiconductor layer and each disposed on a side of the gate electrode, wherein the insulating layer and the gate insulating film are mutually different in at least either one of effective work function and fixed charge amount.

Consequently, it is made possible to control the potential of the active region of the field effect transistor at the back gate electrode without being limited by the disposition of the gate electrode, source/drain contacts, and the like. This makes it possible to improve the rise characteristic of the drain current in the subthreshold region while controlling complication of the manufacturing process, as well as to alleviate the electric field of the channel end on the drain side. Therefore, it is made possible to reduce the off-leak current while making the transistor operate at a low voltage and thus to reduce operating and standby power consumption, as well as to make the field effect transistor highly voltage resistant.

Further, by setting the insulating layer and the gate insulating film so as to be mutually different in at least either one of effective work function and fixed charge amount, it is made possible to make a change to the threshold voltage of the field effect transistor by several volts even when the body region of the semiconductor layer is doped intrinsically or in a low concentration. This makes it possible to lower the dopant concentration of the semiconductor layer regardless of whether the threshold voltage is high or low, to improve carrier mobility of the field effect transistor, and to increase the on-current. Further, since it is made possible to lower the impurity concentration of the semiconductor layer, it is made possible to obtain a steep subthreshold characteristic even when the semiconductor layer is made thicker insofar as the short channel effect is suppressed. Therefore, it is made possible to reduce variations in transistor characteristics as well as to improve the manufacturing yield, reducing the cost.

In the semiconductor device according to the sixth aspect of the invention, the gate insulating film and the embedded insulating layer are preferably mutually different in at least either one of effective work function and fixed charge amount. Further, the gate insulating film and the embedded insulating layer each preferably consist of a silicon oxide film, a silicon oxide nitride film, a silicon nitride film, a silicon oxide film containing Al, Hf oxide or HfSi oxide that contains Al or Y, Zr oxide or ZrSi oxide containing Al or Y, Hf oxide or HfSi oxide that contains no Al nor Y, or Zr oxide or ZrSi oxide that contains no Al nor Y.

In the semiconductor device according to the sixth aspect of the invention, the gate insulating layer preferably consists of a silicon oxide film or a silicon oxide nitride film, and the embedded insulating layer preferably consists of a silicon nitride film, a silicon oxide film containing Al, Hf oxide containing Al, Zr oxide containing Al, Hf oxide not containing Al, or Zr oxide not containing Al.

Consequently, it is made possible to ensure flatness of the interface between the gate insulating film and the channel and at the same time to reduce the interface state density, as well as to control the threshold voltage of the field effect transistor at a low voltage via the back gate electrode. Therefore, it is made possible to let the transistor operate at a low voltage while suppressing deterioration of the carrier mobility, as well as to obtain a steep subthreshold characteristic while suppressing variations in transistor characteristics. This makes it possible to speed up the field effect transistor while reducing operating power consumption.

In the semiconductor device according to the sixth aspect of the invention, a wiring layer is preferably provided which electrically connects the gate electrode to the back gate electrode.

As a result, it is made possible to perform control so that the back side of the channel region of the field effect transistor has the same potential as the gate electrode and thus to improve control over the potential of the channel region. Therefore, even when the semiconductor layer is made thicker, it is possible to obtain a steep subthreshold characteristic and thus to reduce variations in electrical characteristics caused by variations in the film thickness of the SOI semiconductor layer while reducing the off-leak current.

A method of manufacturing a semiconductor device according to a seventh aspect of the invention includes forming a first semiconductor layer on a semiconductor substrate, forming a second semiconductor layer, which has a smaller etching rate than the first semiconductor layer, on the first semiconductor layer, forming a first exposing section that exposes the semiconductor substrate by penetrating the first and second semiconductor layers, forming a supporter that supports the second semiconductor layer above the semiconductor substrate via the first exposing section, forming a second exposing section that exposes a part of the first semiconductor layer from the second semiconductor layer, forming below the second semiconductor layer a cavity, in which the first semiconductor layer is eliminated, by selectively etching the first semiconductor layer via the second exposing section, forming an embedded insulating layer in such a manner that the embedded insulating layer is embedded in the cavity, forming a gate insulating film on the surface of the second semiconductor layer, and forming a gate electrode on the second semiconductor layer via the gate insulating film, wherein the embedded insulating layer and the gate insulating film are mutually different in at least either one of effective work function and fixed charge amount.

Consequently, even when the second semiconductor layer is laminated on the first semiconductor layer, it is made possible to let an etching gas or etching liquid make contact with the first semiconductor layer via the second exposing section. Therefore, it is made possible to eliminate the first semiconductor layer by using a difference in etching rate between the first and second semiconductor layers while leaving the second semiconductor layer, as well as to form an embedded insulating layer in the cavity below the second semiconductor layer. Further, by providing a supporter that supports the second semiconductor layer above the semiconductor substrate, it is possible to prevent the second semiconductor layer from falling on the semiconductor substrate even when a cavity is formed below the second semiconductor layer. Furthermore, by setting the embedded insulating layer and the gate insulating film so as to be mutually different in at least either one of effective work function and fixed charge amount, it is possible to make a change to the threshold voltage of the field effect transistor by several volts even when the body region of the second semiconductor layer is doped intrinsically or in a low concentration. Therefore, it is made possible to form an SOI transistor on the second semiconductor layer without using any SOI substrate, to obtain a steep subthreshold, and to reduce the off-leak current. This allows price cut of an SOI transistor as well its low voltage driving, low power consumption, and speedup.

A method of manufacturing a semiconductor device according to a eighth aspect of the invention includes forming a first semiconductor layer on a semiconductor substrate, forming a second semiconductor layer, which has a smaller etching rate than the first semiconductor layer, on the first semiconductor layer, forming a first exposing section that exposes the semiconductor substrate by penetrating the first and second semiconductor layers, forming a supporter that supports the second semiconductor layer above the semiconductor substrate via the first exposing section, forming a second exposing section that exposes a part of the first semiconductor layer from the second semiconductor layer, forming below the second semiconductor layer a cavity, in which the first semiconductor layer is eliminated, by selectively etching the first semiconductor layer via the second exposing section, forming an insulating film in both the top and bottom portions of the cavity, forming an embedded back gate electrode in the cavity in such a manner that the top and bottom surfaces of the embedded back gate electrode are interposed between the insulating films, forming a gate insulating film on the surface of the second semiconductor layer, and forming a gate electrode on the second semiconductor layer via the gate insulating film, wherein the insulating layer and the gate insulating film are mutually different in at least either one of effective work function and fixed charge amount.

The method of manufacturing a semiconductor device according to the eighth aspect of the invention preferably further includes cleaning backs of the second and fourth semiconductor layers with an ammonia-hydrogen peroxide solution including Al before forming an insulating layer in both the top and bottom portions of the cavity.

The method of manufacturing a semiconductor device according to the eighth aspect of the invention preferably further includes cleaning backs of the second and fourth semiconductor layers with a hydrofluoric acid before forming the embedded insulating layer.

Consequently, it is made possible to form the embedding back gate electrode in such a manner that it is interposed between the insulating films in the cavity below the second semiconductor layer in which an SOI transistor is formed. Further, by setting the insulating film and the gate insulating film formed on the surface of the second semiconductor layer so as to be mutually different in at least either one of effective work function and fixed charge amount, it is made possible to make a change to the threshold voltage of the field effect transistor by several volts even when the body region of the second semiconductor layer is doped intrinsically or in a low concentration. Therefore, it is made possible to lower the dopant concentration of the second semiconductor layer insofar as the short channel effect is suppressed regardless of whether the threshold voltage is high or low. This makes it possible to improve the carrier mobility of the field effect transistor and thus to increase the on-current.

A method of manufacturing a semiconductor device according to a ninth aspect of the invention includes forming a first semiconductor layer on a semiconductor substrate, forming a second semiconductor layer, which has a smaller etching rate than the first semiconductor layer, on the first semiconductor layer, forming a third semiconductor layer, which has the same composition as the first semiconductor layer, on the second semiconductor layer, forming a fourth semiconductor layer, which has the same composition as the second semiconductor layer, on the third semiconductor layer, forming a first exposing section that exposes the semiconductor substrate by penetrating the first to fourth semiconductor layers, forming in the first exposing section a supporter that supports the second and fourth semiconductor layers above the semiconductor substrate, forming a second exposing section that exposes at least parts of the first and third semiconductor layers, in which the supporter is formed, from the second and fourth semiconductor layers, forming first and second cavities, in which the first and third semiconductor layers are respectively eliminated, by selectively etching the first and third semiconductor layers via the second exposing section, forming an embedded insulating layer in each of the first and second cavities, forming a gate insulating film on the surface of the fourth semiconductor layer, and forming a gate electrode in such a manner that the gate electrode is disposed on the fourth semiconductor layer via the gate insulating film, wherein the embedded insulating layer and the gate insulating film are mutually different in at least either one of effective work function and fixed charge amount.

Consequently, even when the second and fourth semiconductor layers are laminated on the first and third semiconductor layers, respectively, it is made possible to let an etching gas or etching liquid make contact with the first and third semiconductor layers via the second exposing section. Therefore, it is made possible to eliminate the first and third semiconductor layers while leaving the second and fourth semiconductor layers, as well as to form an embedded insulating layer in such a manner that the embedded insulating layer is embedded in each of the first and second cavities below the second and fourth semiconductor layers, respectively. Further, by providing a supporter in such a manner that the supporter is embedded in the first exposing section, it is possible to support the second and fourth semiconductor layers above the semiconductor substrate even when the first and second cavities are formed below the second and fourth semiconductor layers, respectively.

Therefore, it is made possible to dispose the second and fourth semiconductor layers on the embedded insulating layer while reducing occurrence of faults in the second and fourth semiconductor layers. This makes it possible to form an SOI transistor in the fourth semiconductor layer without using any SOI substrate, as well as to dispose a back gate electrode below the SOI transistor.

Further, by setting the embedded insulating layer and the gate insulating film so as to be mutually different in at least either one of effective work function and fixed charge amount, it is made possible to make a change to the threshold voltage of the field effect transistor by several volts even when the body region of the fourth semiconductor layer is doped intrinsically or in a low concentration. This makes it possible to lower the dopant concentration of the fourth semiconductor layer regardless of whether the threshold voltage is high or low, to improve the carrier mobility of the field effect transistors, and thus to increase the on-current.

The method of manufacturing a semiconductor device according to the ninth aspect of the invention preferably further includes cleaning backs of the second and fourth semiconductor layers with an ammonia-hydrogen peroxide solution including Al before forming the embedded insulating layer.

Consequently, it is made possible to make the embedded insulating layer have a negative fixed charge and thus to make a change to the threshold voltage of the field effective transistor by several volts even when the body region of the fourth semiconductor layer is doped intrinsically or in a low concentration.

The method of manufacturing a semiconductor device according to the ninth aspect of the invention preferably further includes cleaning backs of the second and fourth semiconductor layers with a hydrofluoric acid before forming the embedded insulating layer.

Consequently, it is made possible to make the embedded insulating layer have a positive fixed charge and thus to make a change to the threshold voltage of the field effective transistor by several volts even when the body region of the fourth semiconductor layer is doped intrinsically or in a low concentration.

In the method of manufacturing a semiconductor device according to the ninth aspect of the invention, the semiconductor substrate and the second semiconductor layer each preferably consist of single-crystal Si, and the first semiconductor layer preferably consists of single-crystal SiGe.

In the method of manufacturing a semiconductor device according to the ninth aspect of the invention, the semiconductor substrate and the second and fourth semiconductor layers each preferably consist of single-crystal Si, and the first and third semiconductor layers each preferably consist of single-crystal SiGe.

Consequently, it is made possible to make the etching rates of the first and third semiconductor layers larger than those of the semiconductor substrate and the second and fourth semiconductor layers while obtaining a lattice match between the semiconductor substrate and the first to fourth semiconductor layers. Therefore, it is made possible to form the second and fourth semiconductor layers, which have good crystal quality, on the first and third semiconductor layers, respectively. This allows insulation between the second and fourth semiconductor layers and the semiconductor substrate without losing the quality of the second and fourth semiconductor layers.

### BRIEF DESCRIPTION OF THE DRAWINGS

The invention will be described with reference to the accompanying drawings, wherein like numbers reference like elements.

FIGS. 1A to 1D show a method of manufacturing a semiconductor device according to a first embodiment of the invention.

FIGS. 2A to 2D show a method of manufacturing a semiconductor device according to the first embodiment of the invention.

FIGS. 3A to 3D show a method of manufacturing a semiconductor device according to the first embodiment of the invention.

FIGS. 4A to 4D show a method of manufacturing a semiconductor device according to the first embodiment of the invention.

FIGS. 5A to 5D show a method of manufacturing a semiconductor device according to the first embodiment of the invention.

FIGS. 6A to 6D show a method of manufacturing a semiconductor device according to the first embodiment of the invention.

FIGS. 7A to 7D show a method of manufacturing a semiconductor device according to the first embodiment of the invention.

FIGS. 8A to 8D show a method of manufacturing a semiconductor device according to the first embodiment of the invention.

FIGS. 9A to 9D show a method of manufacturing a semiconductor device according to a second embodiment of the invention.

FIGS. 10A to 10D show a method of manufacturing a semiconductor device according to the second embodiment of the invention.

FIGS. 11A to 11D show a method of manufacturing a semiconductor device according to the second embodiment of the invention.

FIGS. 12A to 12D show a method of manufacturing a semiconductor device according to the second embodiment of the invention.

FIGS. 13A to 13D show a method of manufacturing a semiconductor device according to the second embodiment of the invention.

FIG. 14A to 14D show a method of manufacturing a semiconductor device according to the second embodiment of the invention.

FIG. 15A to 15D show a method of manufacturing a semiconductor device according to the second embodiment of the invention.

FIGS. 16A to 16D show a method of manufacturing a semiconductor device according to the second embodiment of the invention.

FIGS. 17A to 17D show a method of manufacturing a semiconductor device according to a third embodiment of the invention.

FIGS. 18A to 18C show a method of manufacturing a semiconductor device according to the third embodiment of the invention.

FIGS. 19A to 19C show a method of manufacturing a semiconductor device according to the third embodiment of the invention.

FIGS. 20A to 20C show a method of manufacturing a semiconductor device according to the third embodiment of the invention.

FIGS. 21A to 21C show a method of manufacturing a semiconductor device according to the third embodiment of the invention.

FIGS. 22A to 22C show a method of manufacturing a semiconductor device according to the third embodiment of the invention.

FIGS. 23A to 23C show a method of manufacturing a semiconductor device according to the third embodiment of the invention.

FIGS. 24A to 24C show a method of manufacturing a semiconductor device according to the third embodiment of the invention.

FIGS. 25A to 25C show a method of manufacturing a semiconductor device according to the third embodiment of the invention.

FIGS. 26A to 26C show a method of manufacturing a semiconductor device according to the third embodiment of the invention.

FIGS. 27A to 27C show a method of manufacturing a semiconductor device according to a fourth embodiment of the invention.

FIGS. 28A to 28C show a method of manufacturing a semiconductor device according to the fourth embodiment of the invention.

FIGS. 29A to 29C show a method of manufacturing a semiconductor device according to the fourth embodiment of the invention.

FIGS. 30A to 30C show a method of manufacturing a semiconductor device according to the fourth embodiment of the invention.

FIGS. 31A to 31C show a method of manufacturing a semiconductor device according to the fourth embodiment of the invention.

FIGS. 32A to 32C show a method of manufacturing a semiconductor device according to the fourth embodiment of the invention.

FIGS. 33A to 33C show a method of manufacturing a semiconductor device according to the fourth embodiment of the invention.

FIGS. 34A to 34C show a method of manufacturing a semiconductor device according to the fourth embodiment of the invention.

FIGS. 35A to 35C show a method of manufacturing a semiconductor device according to the fourth embodiment of the invention.

### DESCRIPTION OF EXEMPLARY EMBODIMENTS

Semiconductor devices and methods of manufacturing the same according to the embodiments of the invention will now be described with reference to the accompanying drawings.

### First Embodiment

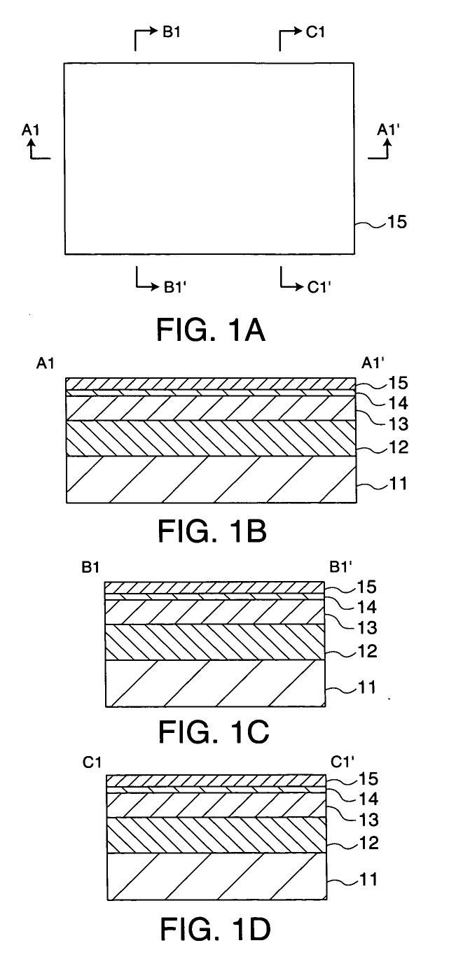

FIGS. 1A to 8A are top views each showing a method of manufacturing a semiconductor device according to a first embodiment of the invention, FIGS. 1B to 8B are cross sections along the lines A1-A1′ to A8-A8′ of FIGS. 1A to 8A, and FIGS. 1C to 8C are cross sections along the lines B1-B1′ to B8-B8′ of FIGS. 1A to 8A.

In FIGS. 1A to 1D, a first semiconductor layer 12 is formed on a semiconductor substrate 11 by epitaxial growth, and a second semiconductor layer 13 is formed on the first semiconductor layer 12 by epitaxial growth. As the first semiconductor layer 12A, it is possible to use a material that has a larger etching rate than the semiconductor substrate 11 and the second semiconductor layer 13. As materials of the semiconductor substrate 11, the first semiconductor layer 12, and the second semiconductor layer 13, it is possible to use a combination of what are selected from among Si, Ge, SiGe, SiC, SiSn, PbS, GaAs, InP, GaP, GaN, ZnSe, or the like. In particular, when the semiconductor substrate 11 is single crystal Si, it is preferable that single crystal SiGe (Ge 10-50%) be used as the first semiconductor layer 12, and single crystal Si as the second semiconductor layer 13. Consequently, it is made possible to obtain a lattice match between the first semiconductor layer 12 and the second semiconductor layer 13, as well as to secure the selection ratio between the first semiconductor layer 12 and the second semiconductor layer 13. Besides a single crystal semiconductor layer, it is also possible to use a polycrystalline semiconductor layer, an amorphous semiconductor layer, or a porous semiconductor layer as the first semiconductor layer 12. Instead of the first semiconductor layer 12, it is also possible to use a metallic oxide film, such as y-aluminum oxide, from which a single crystal semiconductor layer can be grown by epitaxial growth. It is possible to make the thickness of the first semiconductor layer 12 and the second semiconductor layer 13, for example, about 1 to 200 nm.

Thereafter, a base oxidation film 14 is formed on the second semiconductor 13 by thermal oxidation of the second semiconductor layer 13. Then an oxidation prevention film 15 is formed entirely on the base oxidation film 14 by a method such as CVD. As the oxidation prevention surface protection film 15, it is possible to use, for example, a silicon nitride film. Besides functioning as an oxidation prevention film, it is also possible to make the oxidation prevention film 15 function as a stopper layer for the planarization process by CMP (Chemical Mechanical Polishing).

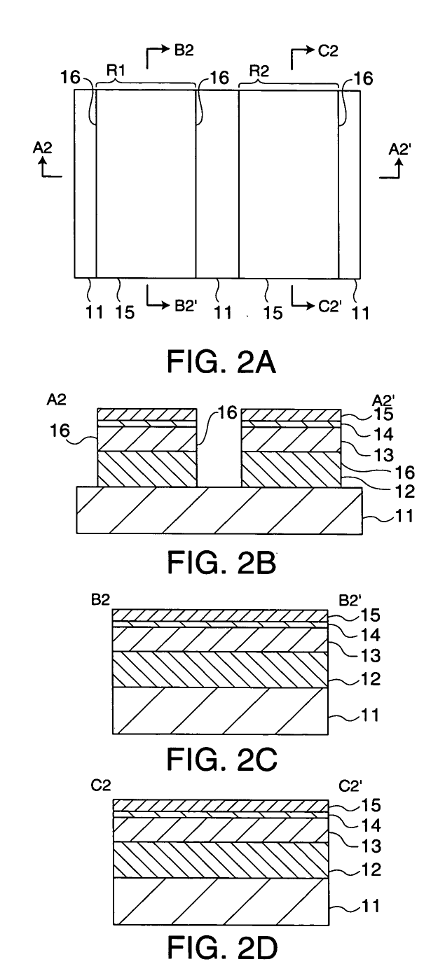

As shown in FIG. 2, the oxidation prevention film 15, the base oxidation film 14, the second semiconductor film 13, and the first semiconductor film 12 are patterned using photolithography and etching. This forms a groove 16 that exposes a part of the semiconductor substrate 11 and divides the second semiconductor layer 13 and the first semiconductor layer 12 into a first region R1 and a second region R2. When exposing a part of the semiconductor substrate 11, etching may be stopped on the surface of the semiconductor substrate 11, or a concave portion may be formed in the semiconductor substrate 11 by over-etching the semiconductor substrate 11. It is possible to make the disposing position of the groove 16 correspond to a part of the element isolation region of the second semiconductor layer 13.

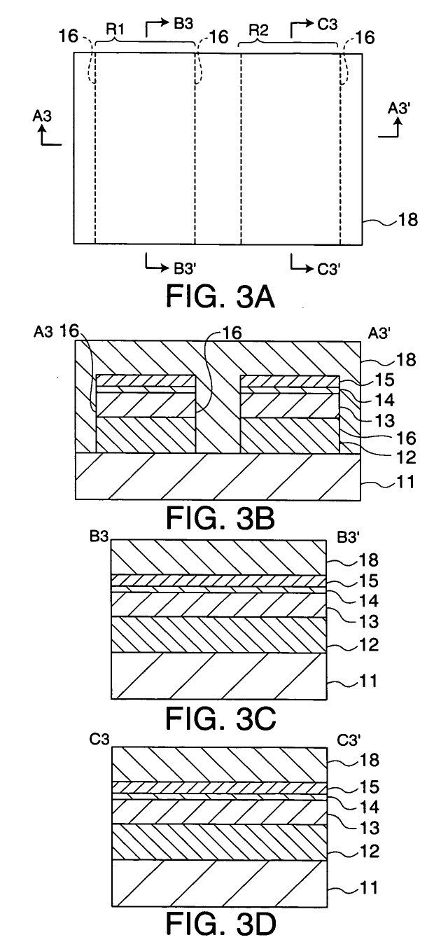

Then, as shown in FIG. 3, a supporter 18 is formed by a method such as CVD in such a manner that it covers the entire surface of the semiconductor substrate 11 and is embedded in the groove 16. The supporter 18 is also formed on the sidewalls of the first semiconductor layer 12 and the second semiconductor layer 13 in the groove 16 so that the second semiconductor layer 13 can be supported above the semiconductor substrate 11. In this case, the supporter 18 formed so as to cover the entire surface of the semiconductor substrate 11 must support the second semiconductor layer 13 while suppressing deformation or the like of the second semiconductor layer 13 and thus maintaining flatness of the second semiconductor layer 13. Therefore, the supporter 18 preferably has a larger film thickness than the minimum element isolation width in view of securing the mechanical strength. An insulator such as silicon oxide film may be used as a material of the supporter 18.

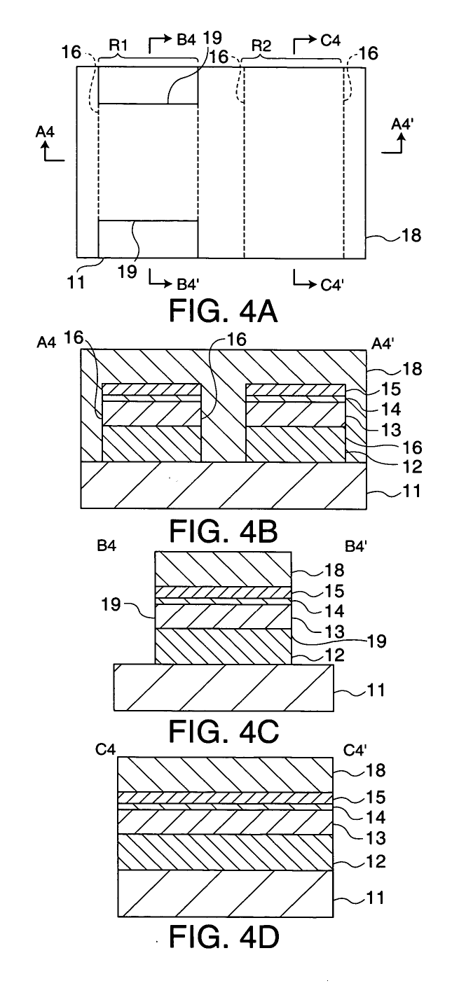

As shown in FIG. 4, by patterning the supporter 18, the oxidation prevention film 15, the base oxidation film 14, the second semiconductor layer 13, and the first semiconductor layer 12 in the first region R1 using photolithography and etching, a groove 19 for exposing a part of the first semiconductor layer 12 in the first region R1 is formed. This makes it possible to prevent the second semiconductor layer 13 and the first semiconductor layer 12 in the second region R2 from being exposed while leaving the first semiconductor layer 12 in the second region R2 covered by the supporter 18. This also makes it possible to make the disposing position of the groove 19 correspond to a part of the element isolation region of the second semiconductor layer 13 in the first region R1.

When exposing a part of the first semiconductor 12, it is possible to stop etching on the surface of the first semiconductor 12, or to over-etch the first semiconductor layer 12 to form a concave portion in the first semiconductor 12. Or, it is possible to conduct etching until the first semiconductor 12 in the groove 19 is penetrated and thus to expose the surface of the semiconductor substrate 11. When stopping etching the first semiconductor layer 12 half way, it is made possible to prevent the surface of the semiconductor substrate 11 in the groove 19 from being exposed. Therefore, it is made possible to reduce the time period during which the semiconductor substrate 11 in the groove 19 is exposed to the etching liquid or etching gas when the first semiconductor layer 12 is etched. This makes it possible to suppress over-etching of the surface of the semiconductor substrate 11 in the groove 19.

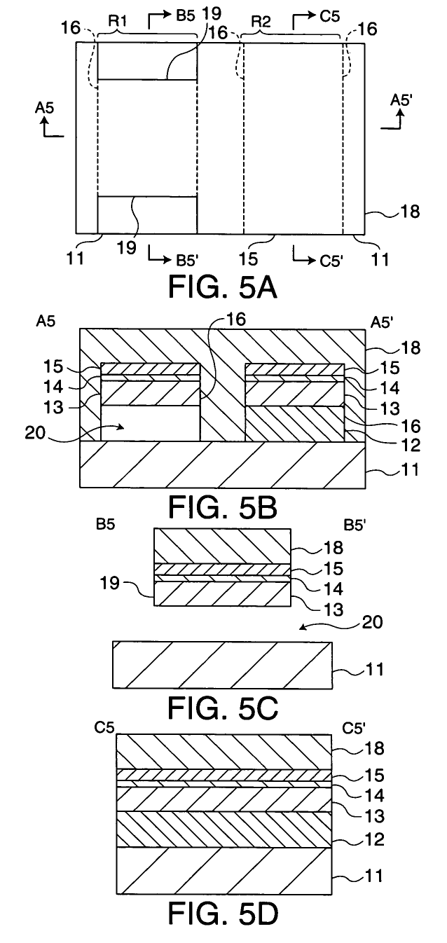

Next, as shown in FIG. 5, by letting the etching gas or etching liquid make contact with the first semiconductor layer 12 in the first region R1 via the groove 19, the first semiconductor layer 12 in the first region R1 is etched, and a cavity 20 is formed between the semiconductor substrate 11 and the second semiconductor layer 13 in the first region R1.

In this case, by providing the supporter 18 in the groove 16, it is made possible to support the second semiconductor layer 13 above the semiconductor substrate 11 even when the first semiconductor layer 12 is eliminated. Further, by providing the groove 19 besides the groove 16, it is made possible to let the first semiconductor layer 12 below the second semiconductor layer 13 make contact with the etching gas or etching liquid. Therefore, it is made possible to achieve insulation between the second semiconductor layer 13 and the semiconductor substrate 11 without losing the quality of the second semiconductor layer 13.

When the semiconductor substrate 11 and the second semiconductor layer 13 are each Si and the first semiconductor layer 12 is SiGe, a hydrofluoric-nitric acid solution (a mixture of hydrofluoric acid, nitric acid, and water) is preferably used as an etching liquid for the first semiconductor layer 12. This makes it possible to eliminate the first semiconductor layer 12 while suppressing over-etching of the semiconductor substrate 11 and the second semiconductor layer 13. It is also possible to use a hydrofluoric nitric acid-peroxide solution, an ammonia hydrogen peroxide solution, a hydrofluoric acetic acid-peroxide solution, or the like as an etching liquid for the first semiconductor layer 12.

Before etching the first semiconductor layer 12, it is possible to make the first semiconductor layer 12 porous by a method such as anodization, to make the first semiconductor layer 12 amorphous by implanting ions into the first semiconductor layer 12, or to use a p-type semiconductor substrate as the semiconductor substrate 11. This makes it possible to increase the etching rate of the first semiconductor layer 12 and thus to enlarge the etching area of the first semiconductor layer 12.

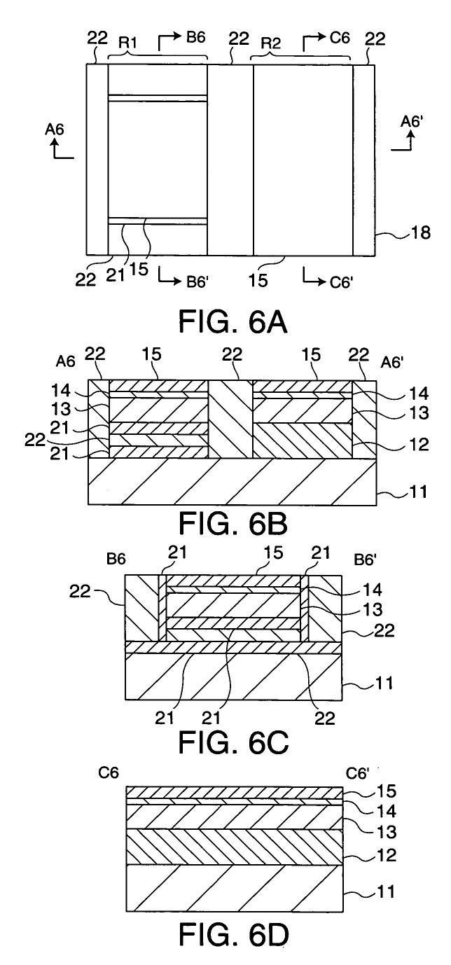

Next, as shown in FIG. 6, an insulating film 21 is formed in the top and bottom portions of the cavity 20 between the semiconductor substrate 11 and the second semiconductor layer 13 by a method such as CVD. Further, an embedded insulating layer 22 is formed in the cavity 20, in which the insulating film 21 is formed, and the groove 19 by a method such as CVD. In FIG. 6, after forming the embedded insulating layer 22, the embedded insulating layer 22 that is accumulated on the entire surface of the semiconductor is eliminated by CMP or etchback.

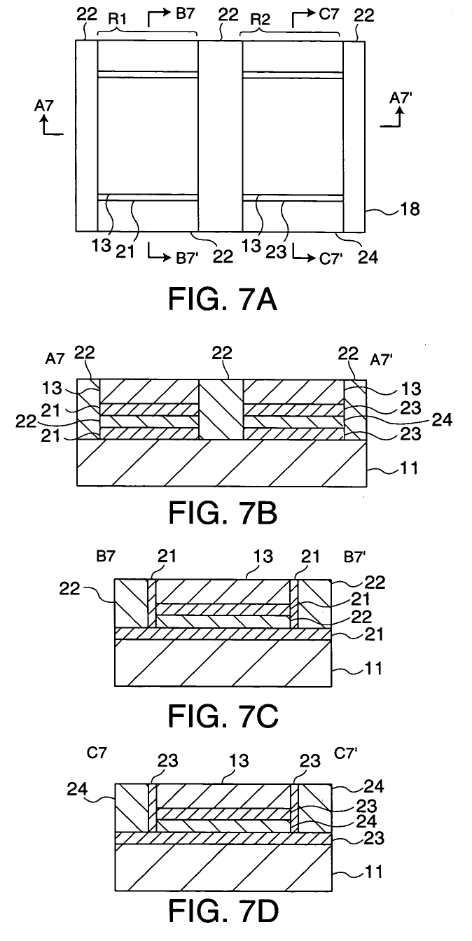

With regard to the second region R2 on the semiconductor substrate 11, as shown in FIG. 7, an insulating film 23 is formed in the top and bottom portions of the cavity 20 between the semiconductor substrate 11 and the second semiconductor layer 13 in the second region R2 by conducting the same treatments as shown in FIGS. 4 to 6. Then, an embedded insulating layer 24 is embedded between the semiconductor substrate 11 and the second semiconductor layer 13 in the second region R2 via the insulating layer 23. The embedded insulating layer 24 is also embedded in a groove in each end of the second semiconductor layer 13 in the second region R2. The insulating films 21 and 23 or the embedded insulating layers 22 and 24 are set so that those films or layers are mutually different in at least either one of effect work function or fixed charge amount. For example, it is possible to use a silicon nitride film, a silicon oxide film including Al, Hf oxide including Al, or Zr oxide including Al as the insulating film 21; and a silicon oxide film not containing Al, Hf oxide not containing Al, Zr oxide not including Al, or the like as the insulating film 23. Specifically, a silicon nitride film may be used as the insulating film 21; a silicon oxide film as the embedded insulating films 22 and 24; and HfAlMOX as the insulating film 23.

As materials of the insulating films 21 and 23 and the embedded insulating layers 22 and 24, it is also possible to use, for example, a silicon nitride film or the like besides a silicon oxide film. Or, as materials of the insulating films 21 and 23 and the embedded insulating layers 22 and 24, it is possible to use an dielectric material such as HfO₂, HfON, HfAlo, HfAlON, HfSiO, HfSiON, ZrO₂, ZrON, ZrAlO, ZrAlON, ZrSiO, ZrSiON, Ta₂O₅, Y₂O₃, (Sr,Ba) TiO₃, LaAlO₃, SrBi₂Ta₂O₉, Bi₄Ti₃O₁₂, or Pb (Zi,Ti) O₃.

As a result, it is made possible to set the respective threshold voltages of a plurality of field effect transistors individually. For example, when using a silicon nitride film as the insulating films 21 and 23, and the embedded insulating layers 22 and 24, it is possible to shift both the threshold voltages of a p-channel field effect transistor and an n-channel field effect transistor in the negative direction. Alternatively, when using HfAlOX as the insulating films 21 and 23 and the embedded insulating layers 22 and 24, it is possible to shift both the threshold voltages of a p-channel field effect transistor and an n-channel field effect transistor in the positive direction as the Al concentration is increased.

Therefore, it is made possible to mix field effect transistors with different threshold voltages on the same semiconductor substrate 11 even when the body region of the second semiconductor layer 13 is doped intrinsically or in a low concentration. It is also made possible to improve the carrier mobility of the field effect transistor regardless of whether the threshold voltage of the field effect transistors is high or low and thus to increase the on-current. Since it is made possible to lower the impurity concentration of the second semiconductor layer 13, it is made possible obtain a steep subthreshold characteristic even when the second semiconductor layer 13 is made thicker. Therefore, even when a field effect transistor is formed in the second semiconductor layer 13, it is made possible to reduce variations in transistor characteristics caused by variations in the film thickness of the second semiconductor layer 13 while optimizing the threshold voltage for each field effect transistor. It is also made possible to improve the manufacturing yield, reducing the cost.

To control the threshold voltage of the field effect transistor, it is possible to let the insulating films 21 and 23 and the embedded insulating layers 22 and 24 have a negative or positive charge in the pre-cleaning process. When letting the insulating layers 21 and 23 and the embedded insulating layers 22 and 24 have a negative charge, it is possible to clean the back of the second semiconductor layer 13 with an ammonia hydrogen peroxide solution before forming the insulating layers 21 and 23 and the embedded insulating layers 22 and 24. Alternatively, when letting the insulating layers 21 and 23 and the embedded insulating layers 22 and 24 have a positive charge, it is possible to clean the back of the second semiconductor layer 13 with a hydrofluoric acid before forming the insulating layers 21 and 23 and the embedded insulating layers 22 and 24.

Further, the insulating films 21 and 23, the embedded insulating films 22 and 24, and the supporter 18 are each made thinner by a method such as CMP or etchback, and planarization by CMP is stopped with the oxidation prevention film used as a stopper layer. Subsequently, by eliminating the base oxide film 14 and the oxidation prevention film 15, the surface of the second semiconductor layer 13 in the first region R1 and the second region R2 is exposed.

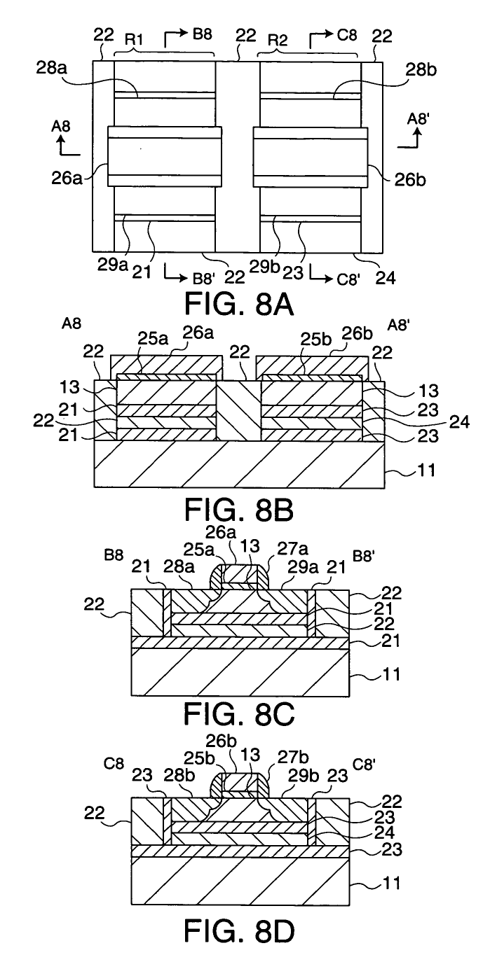

Next, as shown in FIG. 8, by subjecting the surface of the second semiconductor layer 13 to thermal oxidization, ALD, or CVD, gate insulating films 25a and 25b are formed on the surface of the second semiconductor layer 13 in the first region R1 and the second region R2. A polycrystalline silicon layer, a silicide layer, or a metal layer is formed on the second semiconductor layer 13, on which the gate insulating films 25a and 25b are formed, by a method such as CVD. Then, by patterning the polycrystalline silicon layer, the silicide layer, or the metal layer by photolithography or etching, gate electrode 26a and 26b are formed on the gate insulating films 25a and 25b, respectively.

Next, by ion-implanting impurities, such as As, P, and B, into the second semiconductor layer 13 with the gate electrodes 26a and 26b as a mask, an LDD layer, which is disposed on both sides of each of the gate electrodes 26a and 26b and consists of a low density impurity implanting layer, is formed in the second semiconductor layer 13. Then, by forming an insulating layer on the second semiconductor layer 13, in which the LDD layer is formed, using a method such as CVD, and then by etching back the insulating layer using anisotropic etching such as RIE, sidewalls 27a and 27b are formed on the sides of the gate electrodes 26a and 26b, respectively. Then, by ion-implanting impurities, such as As, P, and B, into the second semiconductor layer 13 with the gate electrodes 26a and 26b and the sidewalls 27a and 27b used a mask, source layers 28a and 28b and drain layers 29a and 29b, which are disposed on the sides of the sidewalls 27a and 27b, respectively, and consist of a high density impurity implanting layer, are formed in the second semiconductor layer 13.

As a result, it is made possible to dispose the second semiconductor layer 13 on the embedded insulating layers 22 and 24 while reducing occurrence of faults in the second semiconductor layer 13, as well as to form SOI transistors with different threshold voltages while suppressing cost increase.

### Second Embodiment

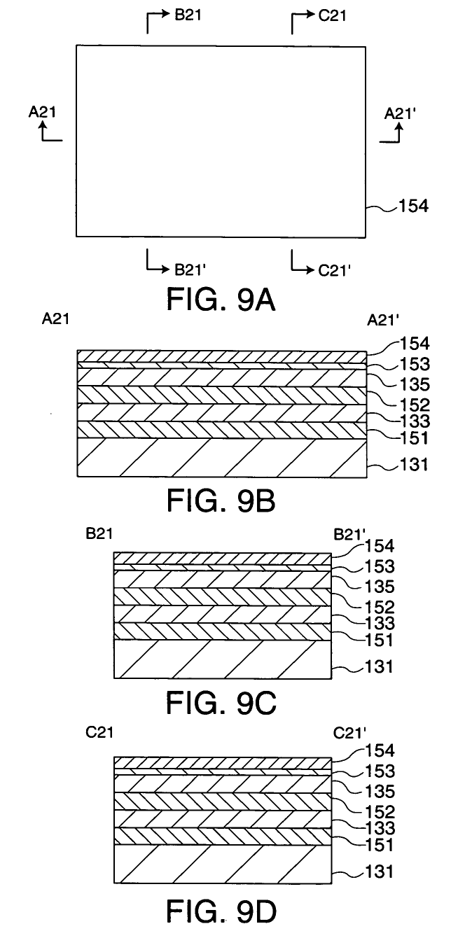

FIGS. 9A to 16A are top views each showing a method of manufacturing a semiconductor device according to a second embodiment of the invention, FIGS. 9B to 9B are cross sections along the lines A21-A21′ to A28-A28′ of FIGS. 9A to 16A, and FIGS. 9C to 16C are cross sections along the lines B21-B21′ to B28-B28′ of FIGS. 9A to 16A.

In FIG. 9, semiconductor layer 151, 133, 152, and 135 are sequentially formed on a semiconductor substrate 131 by epitaxial growth. As the semiconductor layers 151 and 152, it is possible to use a material with a larger etching rate than the semiconductor substrate 131 and the semiconductor layers 133 and 135. In particular, when the semiconductor substrate 131 is Si, SiGe is preferably used as a material of the semiconductor layers 151 and 152, Si as a material of the semiconductor layers 133 and 135.

Thereafter, a base oxidation film 153 is formed on the surface of the semiconductor layer 135 by thermal oxidation, CVD, or the like of the semiconductor layer 135. Then an oxidation prevention film 154 is formed entirely on the base oxidation film 153 by a method such as CVD.

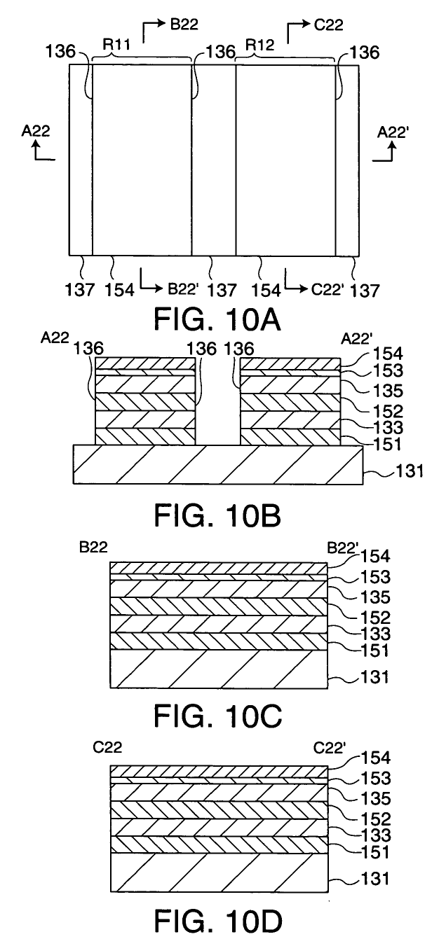

Next, as shown in FIG. 10, by patterning the oxidation prevention film 154, the base oxide film 153, and the semiconductor layers 135, 152, 133, and 151 by photolithography or etching, the semiconductor substrate 131 is exposed, and a groove 136, which divides the semiconductor layers 135, 152, 133, and 151 into the first region R11 and the second region R12, is formed along a prescribed direction.

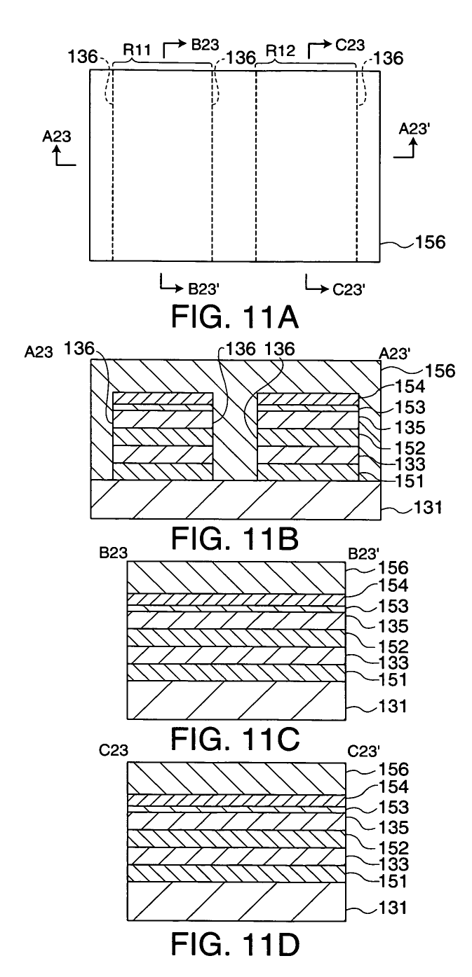

Next, as shown in FIG. 11, a supporter 156 is formed entirely on the semiconductor substrate 131 in such a manner that the supporter 156 is embedded in the groove 136 by a method such as CVD and supports the semiconductor layers 133 and 135 above the semiconductor substrate 131. As a material of the supporter 156, an insulator such as silicon oxide film may be used.

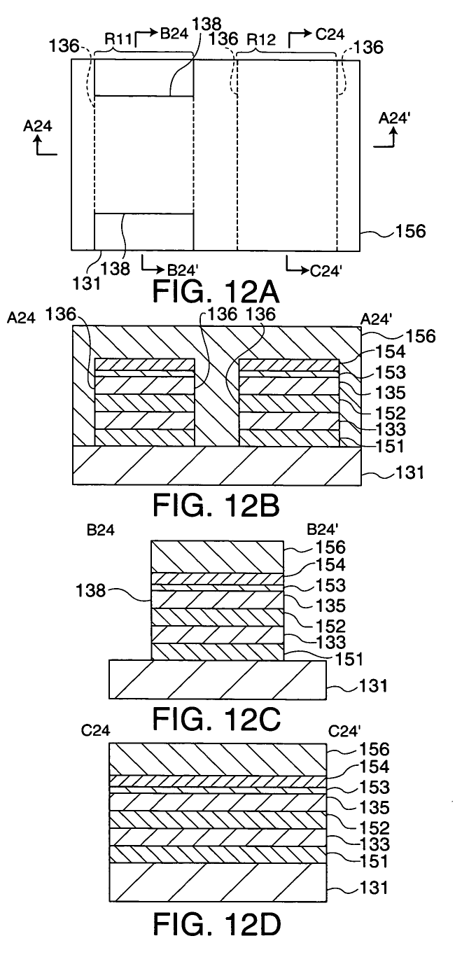

Next, as shown in FIG. 12, by patterning the oxidation prevention film 154, the base oxide film 153, and the semiconductor layers 135, 152, 133, and 151 in the first region R11 by photolithography or etching, a groove 138 for exposing the semiconductor layers 151 and 152 in the first region R11 is formed along a direction perpendicular to the groove 136.

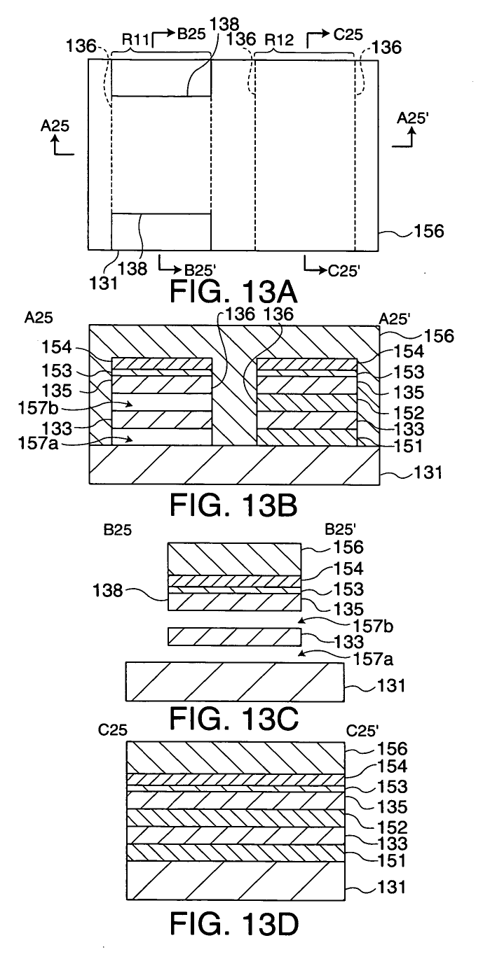

Next, as shown in FIG. 13, by letting the etching gas or etching liquid make contact with the semiconductor layers 151 and 152 via the groove 138, the semiconductor layers 151 and 152 in the first region R11 are etched, a cavity 157a is formed between the semiconductor substrate 131 and the semiconductor layer 133 in the first region R11, and a cavity 157b is formed between the semiconductor layers 133 and 135.

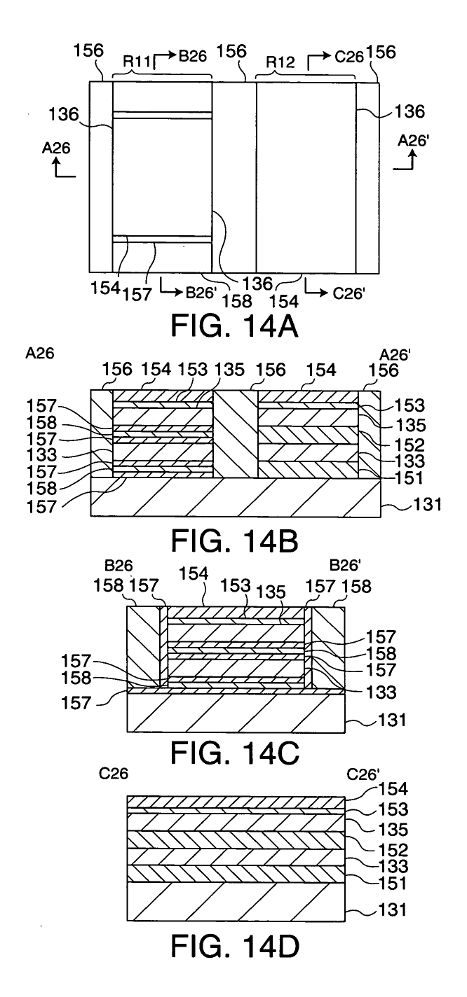

Next, as shown in FIG. 14, an insulating film 157 is formed in the top and bottom portions of cavities 157a and 157b between the semiconductor substrate 131 and the semiconductor layers 133 and 135 in the first region R11 by a method such as CVD. An embedded insulating layer 158 is formed in the cavities 157a and 157b, in which the insulating film 157 is formed, and the groove 138 by a method such as CVD. While an example in which two insulating films are formed in the cavity is shown in the above, only one insulating film may be formed. In FIG. 14, after forming the embedded insulating films 157 and 158 in the cavity, the embedded insulating films 157 and 158 formed entirely on the surface of the semiconductor device are eliminated by CMP or etchback.

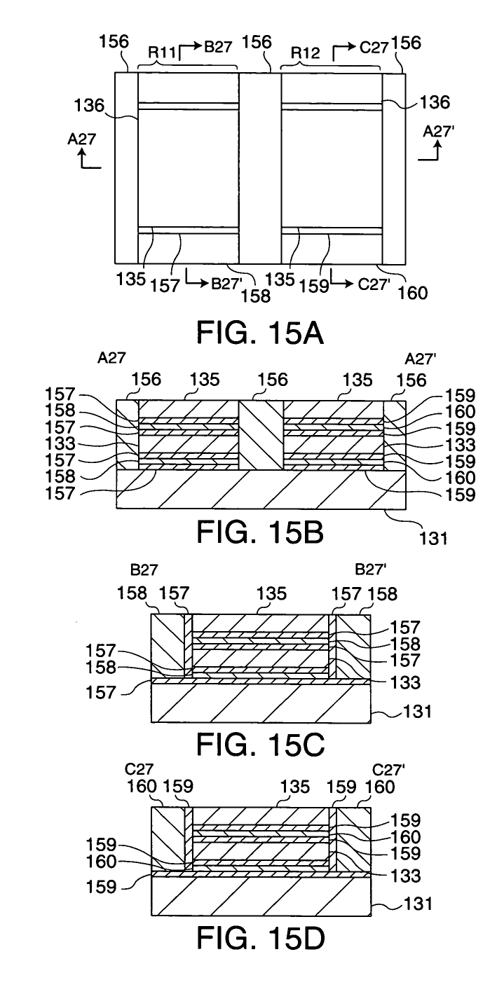

With regard to the second region R12 on the semiconductor substrate 131, as shown in FIG. 15, an insulating film 159 is formed in the top and bottom portions of cavities between the semiconductor substrate 131 and the semiconductor layers 133 and 135 in the second region R12 by conducting the same treatments as shown in FIGS. 12 to 14. Then, an embedded insulating layer 160 is embedded between the semiconductor substrate 131 and the semiconductor layers 133 and 135 in the second region R12 via the insulating layer 159. The embedded insulating layer 160 is also embedded in a groove in each end of the semiconductor layers 133 and 135 in the second region R12. The insulating films 157 and 159 or the embedded insulating layers 158 and 160 are preferably set so that those films or layers are mutually different in at least either one of effect work function or fixed charge amount. For example, it is possible to use a silicon nitride film, a silicon oxide film including Al, Hf oxide including Al, or Zr oxide including Al as the insulating film 157; and a silicon oxide film not containing Al, Hf oxide not containing Al, Zr oxide not including Al, or the like as the insulating film 159. Specifically, HfO_{X} may be used as the insulating film 157; a silicon oxide film as the embedded insulating layers 158 and 160; and HfAlO_{X} as the insulating film 159.

Then, the insulating films 157 and 159, the embedded insulating films 158 and 160, and the supporter 156 are each made thinner by a method such as CMP or etchback. Further, the surface of the semiconductor layer 135 in the first region R11 and the second region R12 is exposed by eliminating the oxidation prevention film 154 and the base oxide film 153. At this point, appropriate element ions are implanted by appropriate acceleration energy, a dopant is selectively introduced into the semiconductor layer 133, and the dopant is electrically activated by annealing.

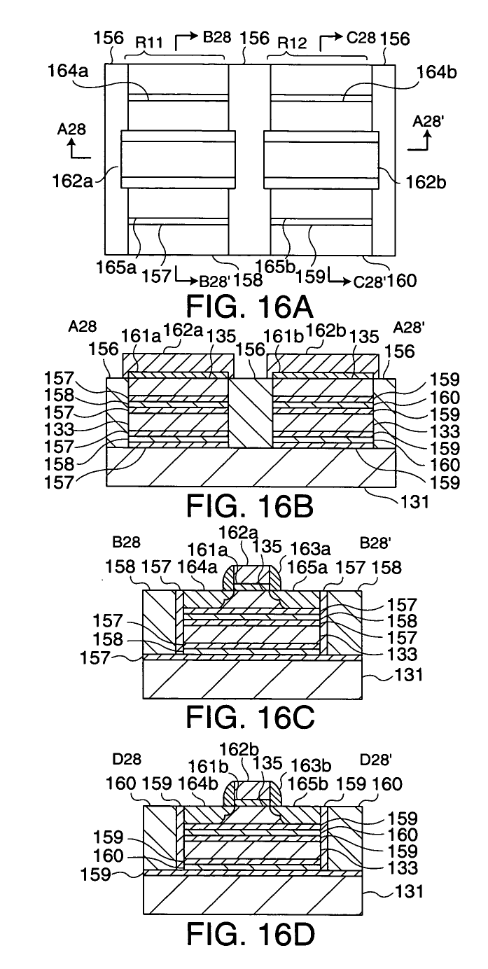

Next, as shown in FIG. 16, by subjecting the surface of the semiconductor layer 135 to thermal oxidization, ALD, or CVD, gate insulating films 161a and 161b are formed on the surface of the semiconductor layer 135 in the first region R11 and the second region R12, respectively. Then, a polycrystalline silicon layer, a silicide layer, or a metal layer is formed on the semiconductor layer 135, on which the gate insulating films 161a and 161b are formed, by a method such as CVD. Then, by patterning the polycrystalline silicon layer, the silicide layer, or the metal layer using photolithography or etching, gate electrode 162a and 162b are formed on the gate insulating films 161a and 161b, respectively. Then, by ion-implanting impurities, such as As, P, and B, into the semiconductor layer 135 with the gate electrodes 162a and 162b used a mask, an LDD layer, which is disposed on both sides of each of the gate electrodes 162a and 162b, respectively, and consists of a low concentration impurity implanting layer, is formed on the semiconductor layer 135. Then, by forming an insulating layer on the semiconductor layer 135, on which the LDD layer is formed, using a method such as CVD, and then by etching back the insulating layer using anisotropic etching such as RIE, sidewalls 163a and 163b are formed on the sides of the gate electrodes 162a and 162b, respectively.

Next, by ion-planting impurities such as As, P, B, and BF₂ into the semiconductor layer 135 with the gate electrodes 162a and 162b used as a mask, source layers 164a and 164b and drain layers 165a and 165b are formed in the semiconductor layer 135 in such a manner that the gate electrode 162a is sandwiched between the source layer 164a and the drain layer 165a, and the gate electrode 162b between the source layer 164b and the drain layer 165b.

Consequently, by using the semiconductor layer 133 as a back gate electrode, it is made possible to control the potential of the active region of the field effect transistor at the back gate electrode without being limited by the disposition of the gate electrode, source/drain contacts, and the like. This makes it possible to control complication of the manufacturing process, as well as to dynamically control the threshold voltage of the field effect transistor by the back gate electrode. Further, when the gate electrode and the back gate electrode are electrically connected, it is made possible to improve the rise characteristic of the drain current in the subthreshold region, as well as to alleviate the electric field of the channel end on the side of the drain layers 165a and 165b. Therefore, it is made possible to reduce the off-leak current while letting the transistor operate at a low voltage and thus to reduce operating and standby power consumption, as well as to make the field effect transistor highly voltage resistant.

### Third Embodiment

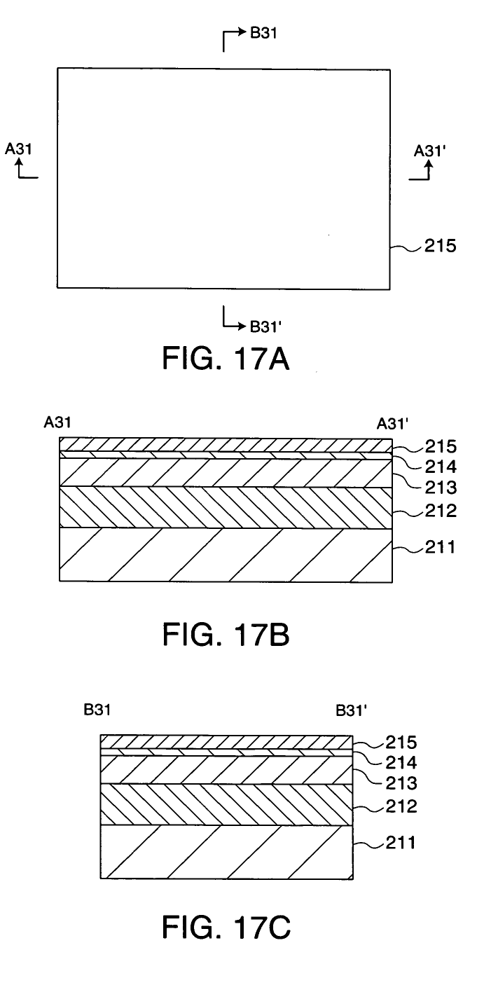

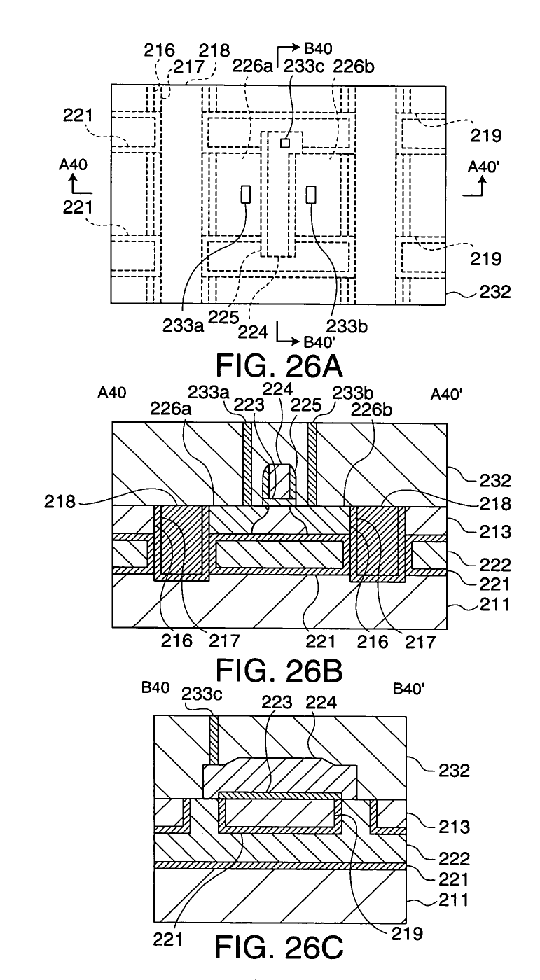

FIGS. 17A to 26A are top views each showing a method of manufacturing a semiconductor device according to a third embodiment of the invention, FIGS. 17B to 17B are cross sections along the lines A31-A31′ to A40-A40′ of FIGS. 17A to 26A, and FIGS. 17C to 26C are cross sections along the lines B31-B31′ to B40-B40′ of FIGS. 17A to 26A.

In FIG. 17, a first semiconductor layer 212 is formed on a semiconductor substrate 211 by epitaxial growth, and a second semiconductor layer 213 is formed on the first semiconductor layer 212 by epitaxial growth. As the first semiconductor layer 212, it is possible to use a material that has a larger etching rate than the semiconductor substrate 211 and the second semiconductor layer 213. As materials of the semiconductor substrate 211, the first semiconductor layer 212, and the second semiconductor layer 213, it is possible to use a combination of what are selected from among Si, Ge, SiGe, SiC, SiSn, PbS, GaAs, InP, GaP, GaN, ZnSe, and the like. In particular, when the semiconductor substrate 211 is Si, it is preferable that SiGe be used as the first semiconductor layer 212, and Si as the second semiconductor layer 213. Consequently, it is made possible to obtain a lattice match between the first semiconductor layer 212 and the second semiconductor layer 213 and at the same time to secure the selection ratio between the first semiconductor layer 212 and the second semiconductor layer 213.

Besides a single crystal semiconductor layer, it is also possible to use a polycrystalline semiconductor layer, an amorphous semiconductor layer, or a porous semiconductor layer as the first semiconductor layer 212. Instead of the first semiconductor layer 212, it is also possible to use a metallic oxide film, such as y-aluminum oxide, from which a single crystal semiconductor layer can be grown by epitaxial growth. It is possible to make the film thickness of the first semiconductor layer 212 and the second semiconductor layer 213, for example, about 1 to 200 nm.

Thereafter, a base oxidation film 214 is formed on the second semiconductor 213 by thermal oxidation of the second semiconductor layer 213. Then an oxidation prevention film 215 is formed entirely on the base oxidation film 14 by a method such as CVD. As the oxidation prevention film 215, it is possible to use, for example, a silicon nitride film. Besides functioning as an oxidation prevention film, it is also possible to make the oxidation prevention film 215 function as a stopper layer for the planarization process by CMP (Chemical Mechanical Polishing).

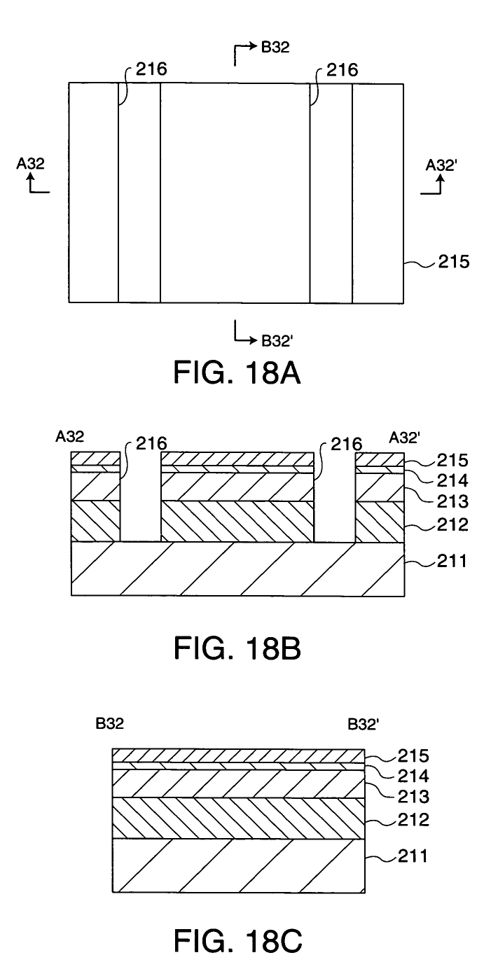

As shown in FIG. 18, the oxidation prevention film 215, the base oxidation film 214, the second semiconductor film 213, and the first semiconductor film 212 are patterned using photolithography and etching. This forms a groove 216 for exposing a part of the semiconductor substrate 211. When exposing a part of the semiconductor substrate 211, etching may be stopped on the surface of the semiconductor substrate 211, or a concave portion may be formed in the semiconductor substrate 211 by over-etching the semiconductor substrate 211. It is possible to make the disposing position of the groove 216 correspond to a part of the element isolation region of the second semiconductor layer 213.

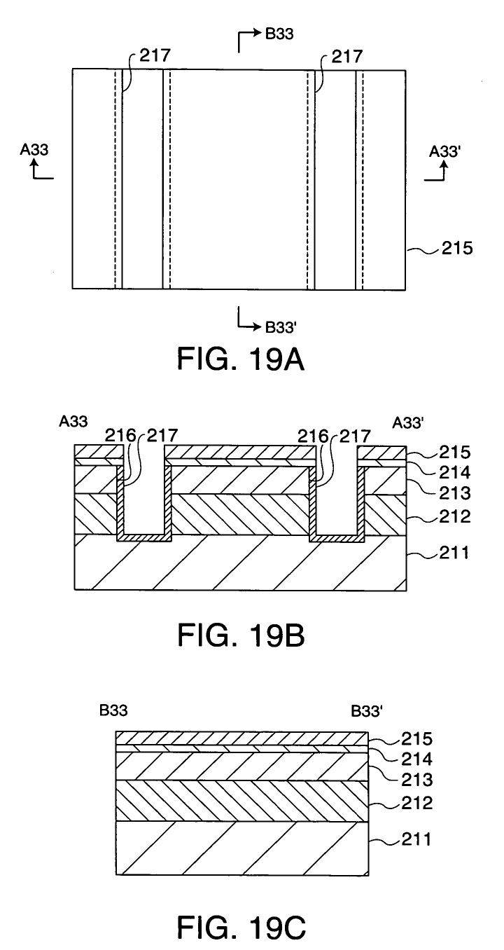

Next, as shown in FIG. 19, a cap layer 217 is formed on the sidewalls of the first semiconductor layer 212 and the second semiconductor layer 213 by selective epitaxial or CVD. As the cap layer 17, a silicon film or the like may be used. Then, with the cap layer 17 formed on the sidewalls of the first semiconductor layer 212 and the second semiconductor layer 213, parts of the first semiconductor layer 212 and the second semiconductor layer 213 are subjected to heat oxidization .

Consequently, it is made possible to form a semiconductor/oxide film interface of a low interface state at least on the sidewall of the second semiconductor layer 213 while suppressing out-diffusion of ingredients contained in the first semiconductor layer 212. At the same time, it is possible to suppress pollution of the surroundings caused by ingredients contained in the first semiconductor layer 212.

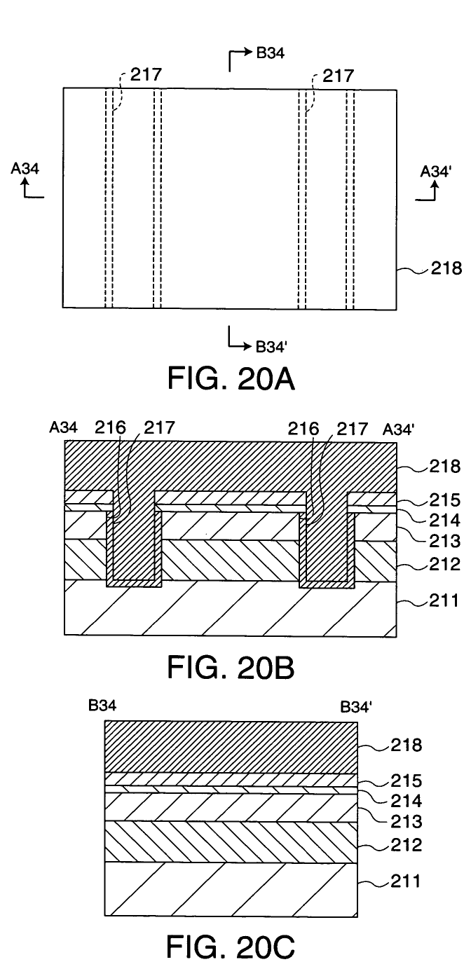

Next, as shown in FIG. 20, a supporter 218 is formed by a method such as CVD in such a manner that the supporter 218 covers the entire surface of the semiconductor substrate 211 and is embedded in the groove 216. The supporter 218 is also formed on the sidewalls of the first semiconductor layer 212 and the second semiconductor layer 213 in the groove 216, and thus the second semiconductor layer 213 can be supported above the semiconductor substrate 211. The supporter 218 formed so as to cover the entire surface of the semiconductor substrate 211 must support the second semiconductor layer 213 while suppressing deformation or the like of the second semiconductor layer 213 and thus maintaining flatness of the second semiconductor layer 213. Therefore, the supporter 218 preferably has a larger film thickness than the minimum element isolation width in view of securing the mechanical strength. As the supporter 218, an element isolation insulator such as silicon oxide film may be used.

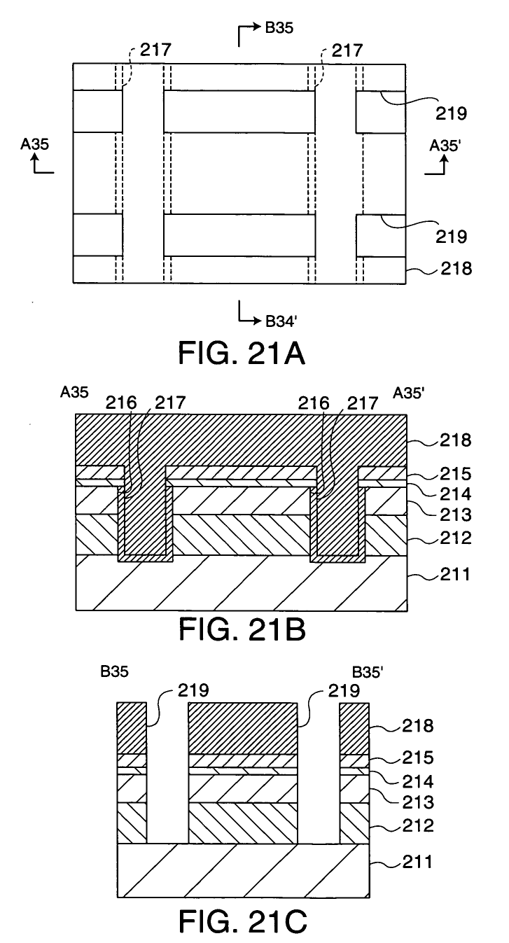

As shown in FIG. 21, by patterning the supporter 218, the oxidation prevention film 215, the base oxidation film 214, the second semiconductor layer 213, and the first semiconductor layer 212 using photolithography and etching, a groove 219 for exposing a part of the first semiconductor layer 212 is formed. It is possible to make the disposing position of the groove 219 correspond to a part of the element isolation region of the second semiconductor layer 213.

When exposing a part of the first semiconductor layer 212, it is possible to stop etching on the surface of the first semiconductor layer 212, or to over-etch the first semiconductor layer 212 to form a concave portion in the first semiconductor layer 212. Or, it is possible to conduct etching until the first semiconductor 212 in the groove 19 is penetrated and thus to expose the surface of the semiconductor substrate 211. By stopping etching the first semiconductor layer 212 half way, it is made possible to prevent the surface of the semiconductor substrate 211 in the groove 219 from being exposed. Therefore, it is made possible to reduce the time period during which the semiconductor substrate 211 in the groove 219 is exposed to the etching liquid or etching gas when the first semiconductor layer 212 is etched. This makes it possible to suppress over-etching of the semiconductor substrate 211 in the groove 219.

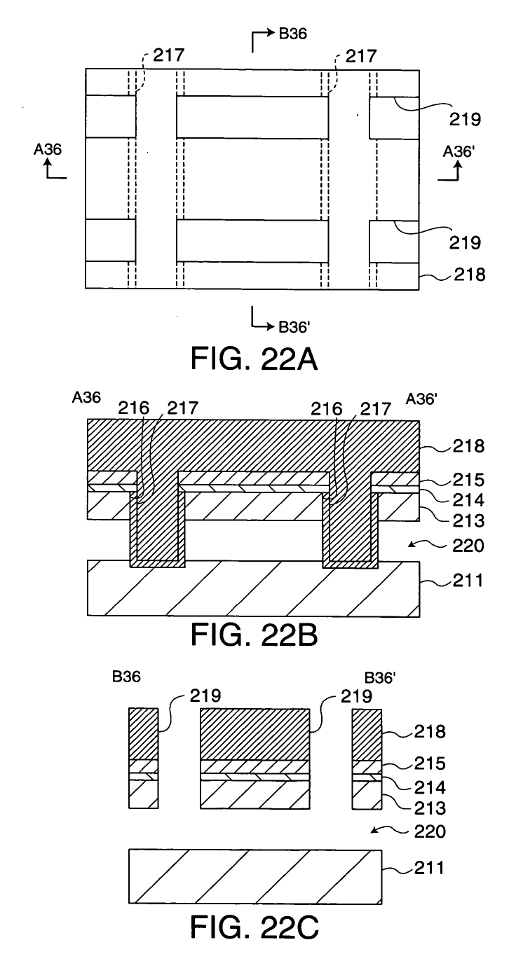

Next, as shown in FIG. 22, by letting the etching gas or etching liquid make contact with the first semiconductor layer 212 via the groove 219, the first semiconductor layer 212 is etched, and a cavity 220 is formed between the semiconductor substrate 211 and the second semiconductor layer 213.

In this case, by providing the supporter 218 in the groove 216, it is made possible to support the second semiconductor layer 213 above the semiconductor substrate 211 even when the first semiconductor layer 212 is eliminated. Further, by providing the groove 219 besides the groove 216, it is made possible to let the first semiconductor layer 212 below the second semiconductor layer 213 make contact with the etching gas or etching liquid. Therefore, it is made possible to achieve insulation between the second semiconductor layer 213 and the semiconductor substrate 211 without losing the quality of the second semiconductor layer 213.

When the semiconductor substrate 211 and the second semiconductor layer 213 are each Si, and the first semiconductor layer 212 is SiGe, a hydrofluoric-nitric acid solution (a mixture of hydrofluoric acid, nitric acid, and water) is preferably used as an etching liquid for the first semiconductor layer 212. This makes it possible to eliminate the first semiconductor layer 212 while suppressing over-etching of the semiconductor substrate 211 and the second semiconductor layer 213. It is also possible to use a hydrofluoric nitric acid-peroxide solution, an ammonia hydrogen peroxide solution, a hydrofluoric acetic acid-peroxide solution, or the like as an etching liquid for the first semiconductor layer 212.

Before eliminating the first semiconductor layer 212 by etching, it is possible to make the first semiconductor layer 212 porous by a method such as anodization, to make the first semiconductor layer 212 amorphous by implanting ions into the first semiconductor layer 212, or to use a p-type semiconductor substrate as the semiconductor substrate 211. This makes it possible to increase the etching rate of the first semiconductor layer 212 and thus to enlarge the etching area of the first semiconductor layer 212.

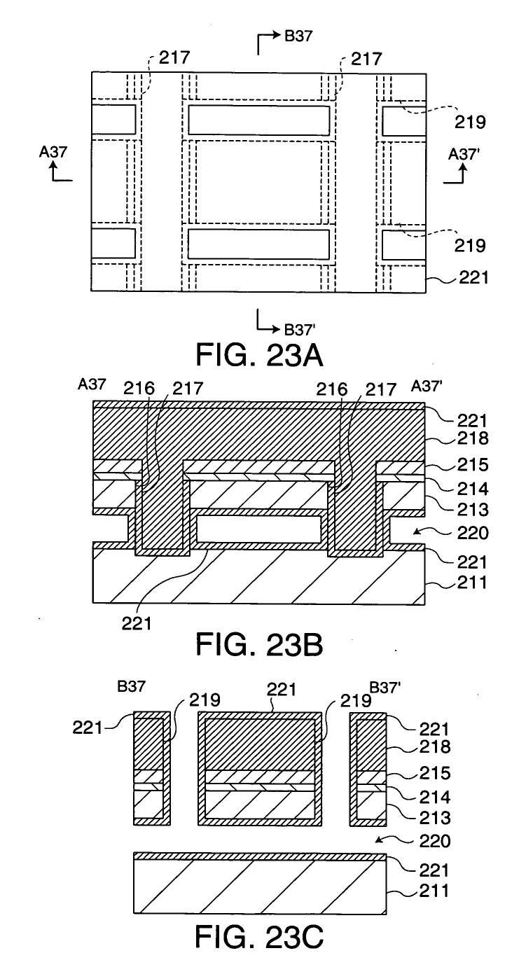

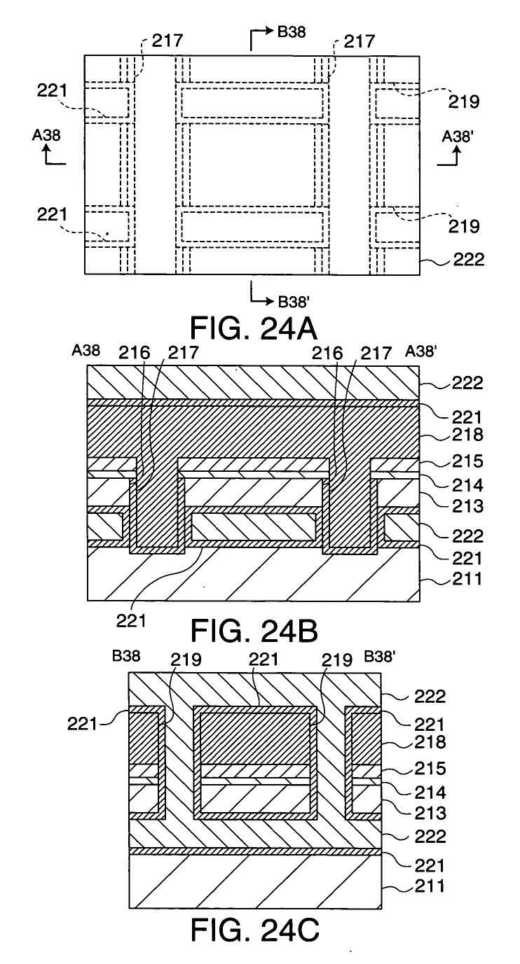

Next, as shown in FIG. 23, an insulating film 221 is formed in the top and bottom portions of a cavity 220 between the semiconductor substrate 211 and the second semiconductor layer 213 by a method such as CVD. Further, as shown in FIG. 24, an embedded insulating layer 222 is formed in the cavity 220, in which the insulating film 221 is formed, and the groove 219 by a method such as CVD. As materials of the insulating film 221 and the embedded insulating layer 222, it is possible to use, for example, a silicon nitride film or the like besides a silicon oxide film. Or, an dielectric material such as HfO₂, HfON, HfAlO, HfAlON, HfSiO, HfSiON, ZrO₂, ZrON, ZrAlO, ZrAlON, ZrSiO, ZrSiON, Ta₂O₅, Y₂O₃, (Sr,Ba) TiO₃, LaAlO₃, SrBi₂Ta₂O₉, Bi₄Ti₃O₁₂, or Pb (Zi,Ti)O₃ may be used. For example, a silicon nitride film may be used as the insulating film 221; and a silicon oxide film as the embedded insulating layer 222.

Consequently, it is possible to control the fixed charge of the insulating film 221 and the embedded insulating layer 222 as well as to control the threshold voltage of the field effect transistor from the back of the second semiconductor layer 213. For example, when a silicon nitride film is used as the insulating film 221 and the embedded insulating layer 222, it is possible to shift both the threshold voltages of a p-channel field effect transistor and a n-channel field effect transistor in the negative direction. Or, when HfAlOX is used as the insulating film 221 and the embedded insulating layer 222, it is possible to shift both the threshold voltages of a p-channel field effect transistor and a n-channel field effect transistor in the positive direction.

Consequently, it is made possible to make a change to the threshold voltage of the field effect transistor using the fixed charge the insulating film 221 and the embedded insulating layer 222 by several volts even when the body region of the second semiconductor layer 213 is doped intrinsically or in a low concentration. Therefore, it is possible to improve the carrier mobility of the field effect transistor regardless of whether the threshold voltage is high or low and thus to increase the on-current. Since it is made possible to lower the impurity concentration of the second semiconductor layer 213, it is possible obtain a steep subthreshold characteristic even when the second semiconductor layer 213 is made thicker insofar as the short channel effect is suppressed. Therefore, even when a field effect transistor is formed in the second semiconductor layer 213, it is possible to reduce variations in transistor characteristics as well as to improve the manufacturing yield, reducing the cost.

To control the threshold voltage of the field effect transistor, it is possible to let the insulating film 221 and the embedded insulating layer 222 have a negative or positive charge in the pre-cleaning process. When letting the insulating layer 221 and the embedded insulating layer 222 have a negative charge, it is possible to clean the back of the second semiconductor layer 213 with an ammonia hydrogen peroxide solution before forming the insulating layer 221 and the embedded insulating layer 222. Alternatively, when letting the insulating layer 221 and the embedded insulating layer 222 have a positive charge, it is possible to clean the back of the second semiconductor layer 213 with a hydrofluoric acid before forming the insulating layer 221 and the embedded insulating layer 222.

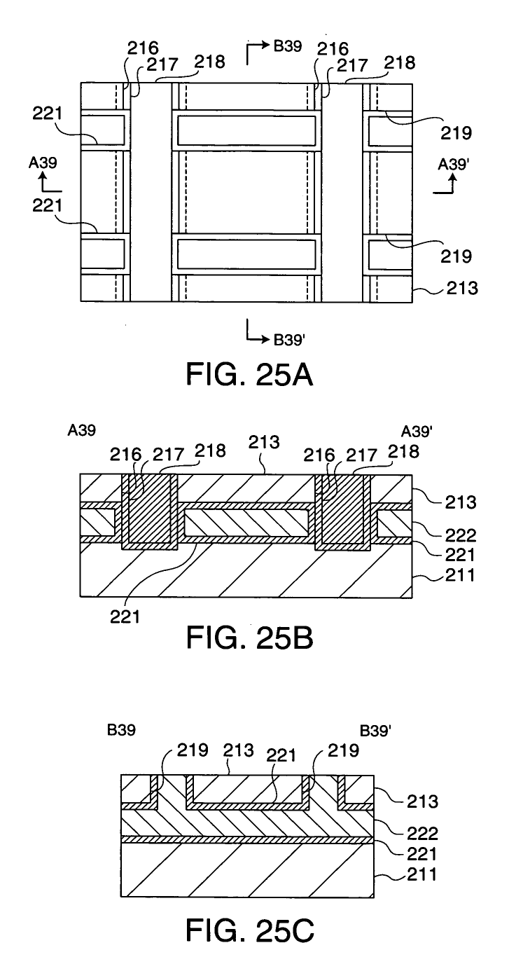

Next, as shown in FIG. 25, the insulating film 221, the embedded insulating film 222, and the supporter 218 are each made thinner by a method such as CMP or etchback, and planarization by CMP is stopped with the oxidation prevention film used as a stopper layer. Thereafter, by eliminating the base oxide film 214 and the oxidation prevention film 215, the surface of the second semiconductor layer 213 is exposed.

Next, as shown in FIG. 25, by subjecting the surface of the second semiconductor layer 213 to thermal oxidization, ALD, or CVD, a gate insulating film 23 is formed on the second semiconductor layer 213. Then, a polycrystalline silicon layer, a silicide layer, or a metal layer is formed on the second semiconductor layer 213, on which the gate insulating film 23 is formed, by a method such as CVD. Then, by patterning the polycrystalline silicon layer, the silicide layer, or the metal layer using photolithography or etching, a gate electrode 224 is formed on the second semiconductor layer 213.

Next, by ion-implanting impurities, such as As, P, and B, into the second semiconductor layer 213 with the gate electrode 224 as a mask, an LDD layer, which is disposed on both sides of each of the gate electrode 224 and consists of a low density impurity implanting layer, is formed in the second semiconductor layer 213. Then, by forming an insulating layer on the second semiconductor layer 213, on which the LDD layer is formed, using a method such as CVD, and then by etching back the insulating layer using anisotropic etching such as RIE, a sidewall 225 is formed on the sidewalls of the gate electrode 224. Then, by ion-implanting impurities, such as As, P, and B, into the second semiconductor layer 213 with the gate electrode 224 and the sidewall 225 used a mask, a source layer 226a and a drain layer 226b, which are disposed on a the sides of the sidewall 225 and consist of a high density impurity implanting layer, are formed on the second semiconductor layer 213.

Next, an inter-layer insulating layer 232 is deposited on the gate electrode 224 by a method such as CVD. Then a source contact electrode 233a, a drain contact electrode 233b, and a gate contact electrode 233c are formed on the inter-layer insulating layer 232 in such a manner that the source contact electrode 233a, the drain contact electrode 233b, and the gate contact electrode 233c are each embedded in the inter-layer insulating layer 232 and connected to the source layer 226a, the drain layer 226b, and the gate electrode 224, respectively.

As a result, it is made possible to dispose the second semiconductor layer 213 on the insulating layer 221 while reducing occurrence of faults in the second semiconductor layer 213, and thus to form an SOI transistor while suppressing cost increase.

The embedded insulating layer 222 and the gate insulating film 224 are preferably mutually different in at least either one of effective work function and fixed charge amount. For example, it is possible to use a silicon oxide film or a silicon oxide nitride film as the gate insulating film 224; a silicon nitride film, a silicon oxide film containing Al, Hf oxide including Al, Zr oxide including Al, Hf oxide not containing Al, Zr oxide not containing Al, or the like as the embedded insulating film 222.

As a result, it is made possible to maintain flatness of the interface between the gate insulating layer 224 and a channel and at the same time to reduce the interface state density. It is also made possible to control the threshold voltage of the field effect transistor while keeping the impurity concentration at a low level even when the second semiconductor layer 213 in the channel region is made thinner. This makes it possible to suppress deterioration of the carrier mobility and to make the field effect transistor operate at a low voltage. This also makes it possible to achieve a steep subthreshold while suppressing variations in transistor characteristic, as well as to speed up the field effect transistor while reducing operating power consumption.

### Fourth Embodiment

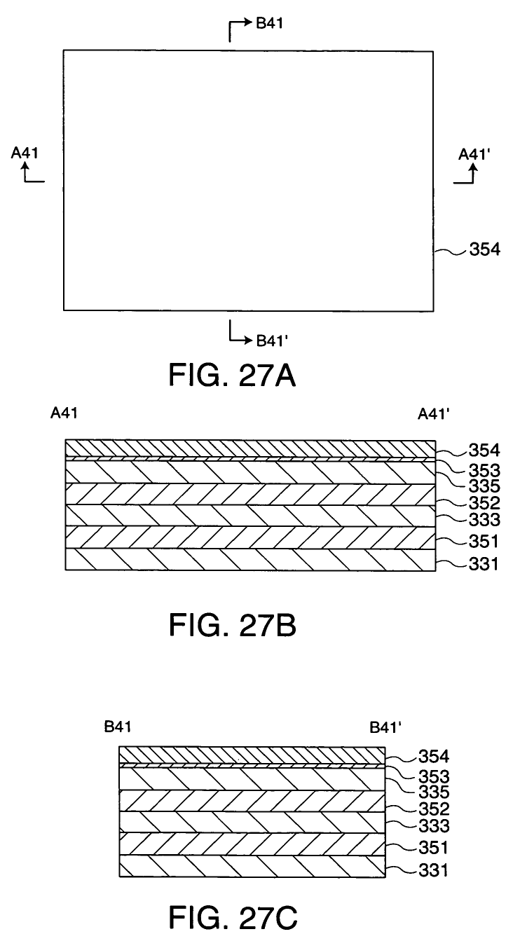

FIGS. 27A to 35A are top views each showing a method of manufacturing a semiconductor device according to a fourth embodiment of the invention, FIGS. 27B to 35B are cross sections along the lines A41-A41′ to A49-A49′ of FIGS. 27A to 35A, and FIGS. 27C to 35C are cross sections along the lines B41-B41′ to B49-B49′ of FIGS. 27A to 35A.

In FIG. 27, semiconductor layers 351, 333, 352, and 335 are sequentially formed on a semiconductor substrate 331 by epitaxial growth. As the semiconductor layers 351 and 352, it is possible to use a material with a larger etching rate than the semiconductor substrate 331 and the semiconductor layers 333 and 335. In particular, when the semiconductor substrate 331 is Si, SiGe is preferably used as the semiconductor layers 351 and 352; and Si as the semiconductor layers 333 and 335.

Thereafter, a base oxidation film 353 is formed on the semiconductor layer 335 by thermal oxidation, CVD, or the like of the semiconductor layer 335. Then an oxidation prevention surface protection film 354 is formed entirely on the base oxidation film 353 by a method such as CVD.

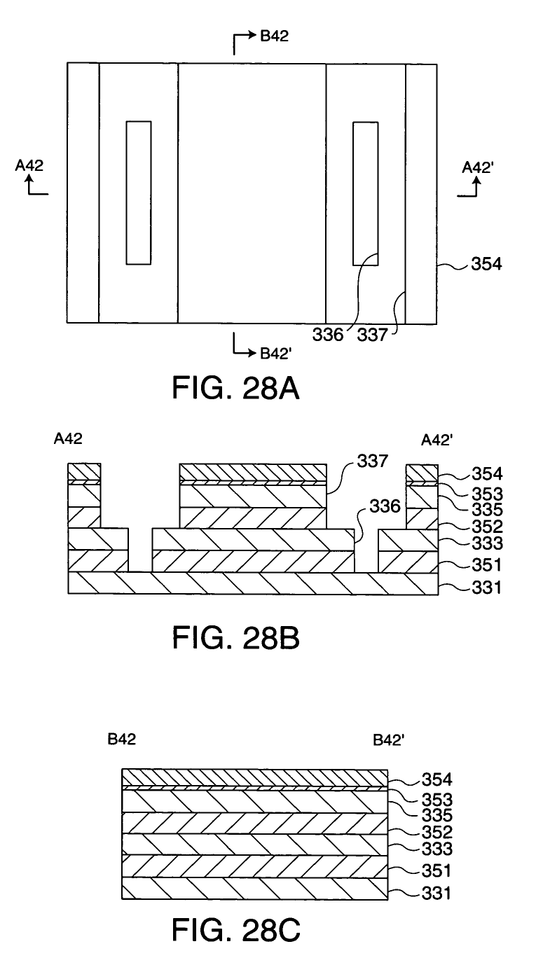

Next, as shown in FIG. 28, by patterning the oxidation prevention film 354, the base oxide film 353, and the semiconductor layers 335, 352, 333, and 351 by photolithography or etching, a groove 336 for exposing the semiconductor substrate 331 is formed along a prescribed direction. Further, by patterning the oxidation prevention film 354, the base oxide film 353, and the semiconductor layers 335 and 352 by photolithography or etching, a groove 337 is formed in such a manner that the groove 37 overlaps with the groove 336, is wider than the groove 336, and exposes the semiconductor layer 333.

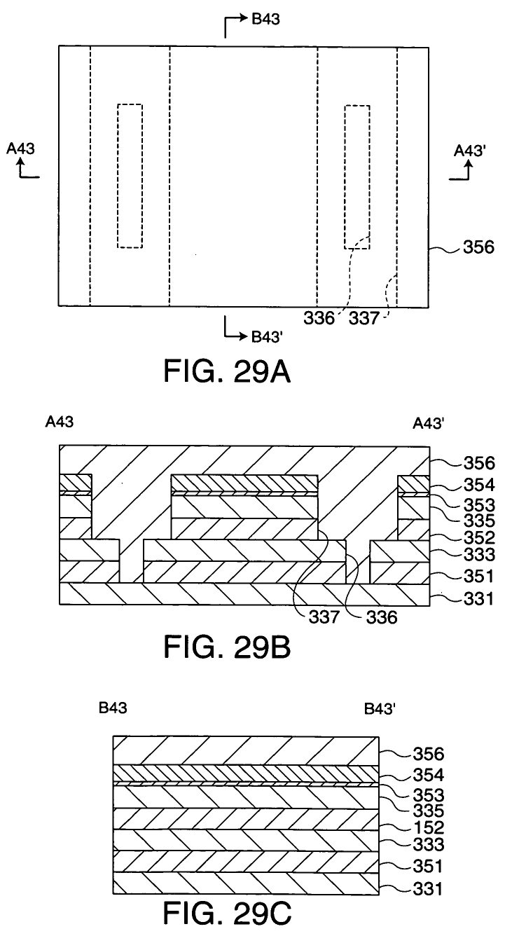

Next, as shown in FIG. 29, a supporter 156 is formed entirely on the semiconductor substrate 331 by a method such as CVD in such a manner that the supporter 156 is embedded in the grooves 336 and 337 and supports the semiconductor layers 333 and 335 above the semiconductor substrate 331. As a material of the supporter 356, an insulator such as silicon oxide film may be used.

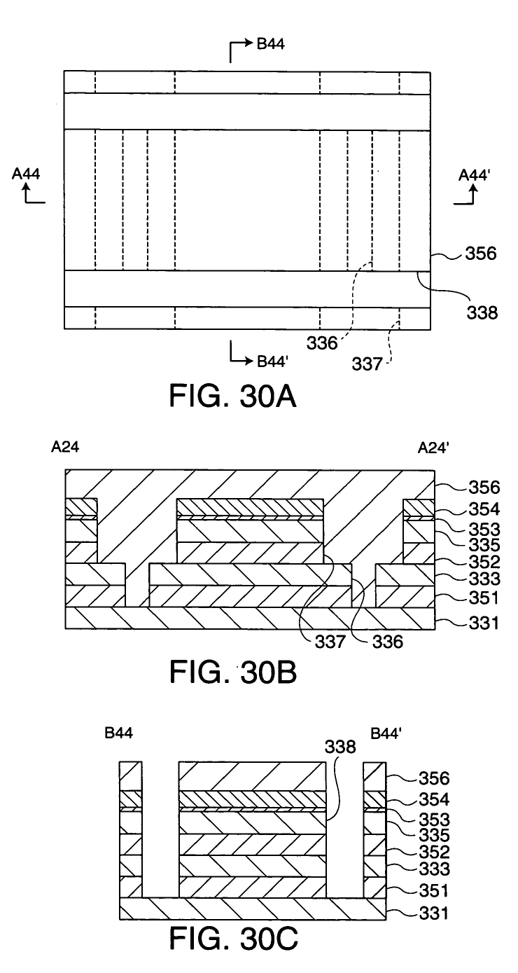

Next, as shown in FIG. 30, by patterning the oxidation prevention film 354, the base oxide film 353, and the semiconductor layers 335, 352, 333, and 351 by photolithography or etching, a groove 138 for exposing the semiconductor substrate 331 is formed along a direction perpendicular to the groove 336.

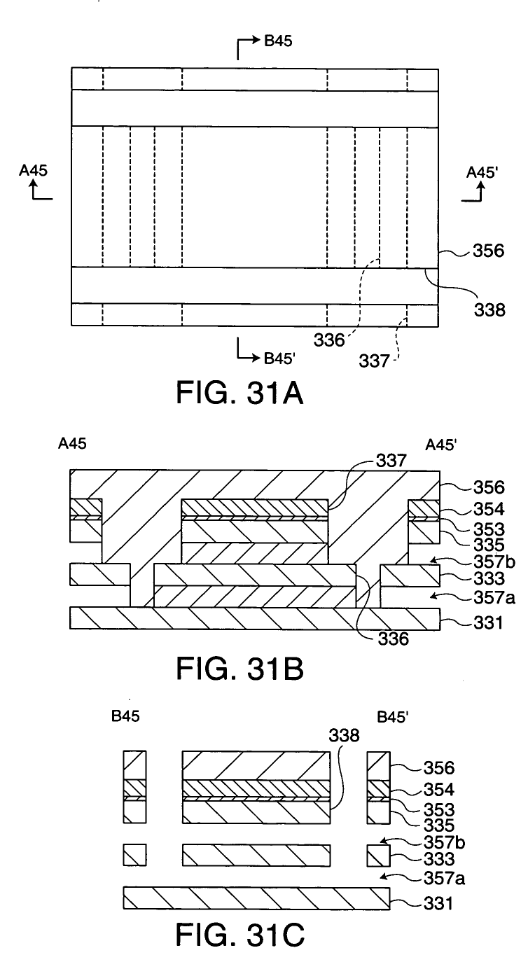

Next, as shown in FIG. 31, by letting the etching gas or etching liquid make contact with the semiconductor layers 351 and 352 via the groove 338, the semiconductor layers 351 and 352 are etched, a cavity 357a is formed between the semiconductor substrate 331 and the semiconductor layer 333, and a cavity 357b is formed between the semiconductor layers 333 and 335.

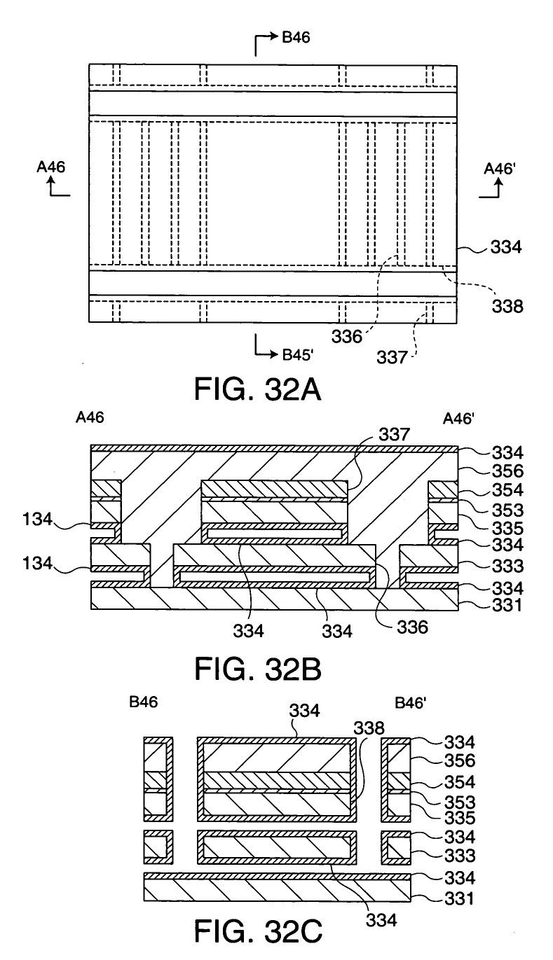

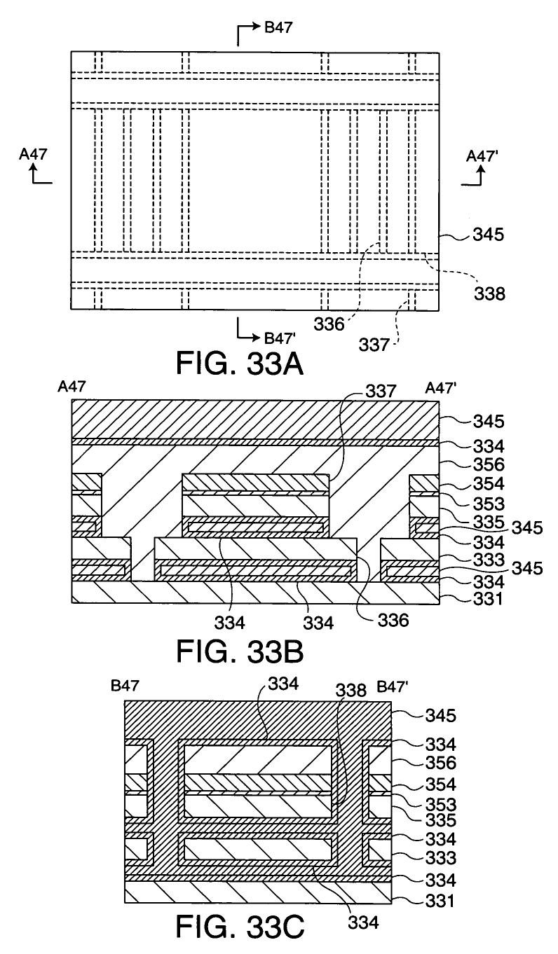

Next, in FIG. 32, an insulating film 334 is formed in the top and bottom portions of a cavity 357a between the semiconductor substrate 331 and the semiconductor layer 333 and of a cavity 357b between the semiconductor layers 333 and 335 by a method such as thermal oxidation or CVD. Further, as shown in FIG. 33, an embedded insulating layer 345 is formed in the cavities 357a and 357b, in which the insulating film 334 is formed, and the groove 338 by a method such as CVD. At this point, appropriate element ions are implanted by appropriate energy, a dopant is introduced selectively into the semiconductor layer 333, and the dopant is electrically activated by annealing.

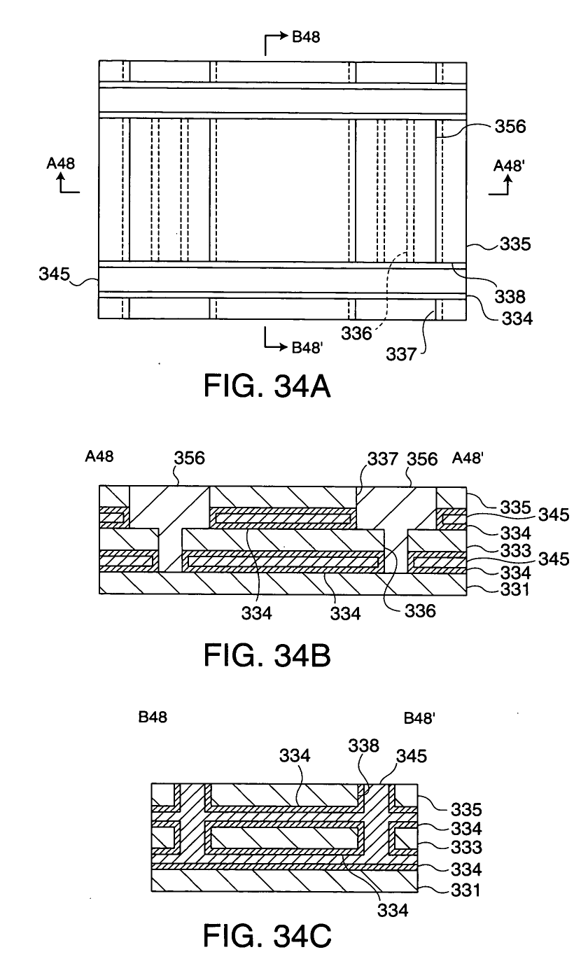

Next, as shown in FIG. 34, the insulating film 334, the embedded insulating layer 345, and the supporter 356 are each made thinner by a method such as CMP or etchback. Further, the oxidation prevention film 354 and the base oxide film 353 are eliminated. Thus, the surface of the semiconductor layer 335 is exposed. The ion implantation conducted in FIG. 33 may be done in FIG. 34 instead of FIG. 33.

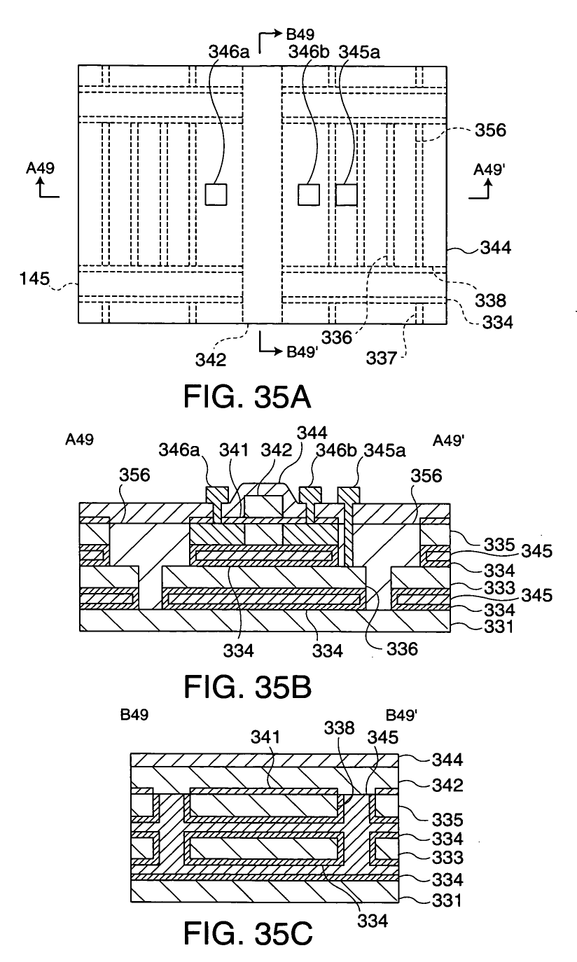

Next, as shown in FIG. 35, by subjecting the surface of the semiconductor layer 335 to thermal oxidization, ALD, or CVD, a gate insulating film 341 is formed on the semiconductor layer 335. Then, a polycrystalline silicon layer, a silicide layer, or a metal layer is formed on the semiconductor layer 335, on which the gate insulating film 341 is formed, by a method such as CVD. Then, by patterning the polycrystalline silicon layer, silicide layer, or metal layer using photolithography or etching, a gate electrode 342 is formed on the semiconductor layer 335. Then, by conducting ion-implantation IP2 of impurities such as As, P, B, and BF₂ into the semiconductor layer 335 with the gate electrode 342 used as a mask, a source layer 343a and a drain layer 343b are formed in the semiconductor layer 335 in such a manner that the gate electrode 342 is sandwiched between the source layer 343a and the drain layer 343b.

Subsequently, an inter-layer insulating layer 344 is deposited on the gate electrode 342 by a method such as CVD. Then a back gate contact electrode 345a is formed on the inter-layer insulating layer 344 in such a manner that the back gate contact electrode 345a is embedded in the inter-layer insulating layer 344 and the supporter 356 and connected to the semiconductor layer 333. Further, a source contact electrode 346a and a drain contact electrode 346b are formed on the inter-layer insulating layer 344 in such a manner that those electrodes are embedded in the inter-layer insulating layer 344 and connected to the source layer 343a and the drain layer 343b, respectively.

Consequently, by using the semiconductor layer 333 as a back gate electrode, it is made possible to control the potential of the active region of the field effect transistor at the back gate electrode without being limited by the disposition of the gate electrode 342, the source contact electrode 346a, the drain contact electrode 346b, and the like. This makes it possible to dynamically control the threshold voltage of the field effect transistor while controlling complication of the manufacturing process. Further, when the gate electrode 342 and the back gate electrode 333 are electrically connected, it is made possible to make the rise characteristic of the drain current in the subthreshold region steep. This makes it possible to reduce the off-leak current while making the transistor operate at a low voltage and to reduce operating and standby power consumption, as well as to make the field effect transistor highly voltage resistant.

It is preferable that the embedded insulating layer 345 and the gate insulating film 341 are mutually different in at least either one of effective work function and fixed charge amount. For example, it is possible to use a silicon oxide film or a silicon oxide nitride film as the gate insulating film 341; a silicon nitride film, a silicon oxide film containing Al, Hf oxide including Al, Zr oxide including Al, Hf oxide not containing Al, Zr oxide not containing Al, or the like as the embedded insulating film 345.

Consequently, it is made possible to make a change to the threshold voltage of the field effective transistor by several volts by the combination of the gate insulating film 341 and the embedded insulating layer 345 even when the body region of the semiconductor layer 335 is doped intrinsically or in a low concentration. This makes it possible to lower the dopant concentration of the semiconductor layer 335 regardless of whether the threshold voltage is high or low, to improve the carrier mobility of the field effect transistor, and thus to increase the on-current. Further, since it is made possible to lower the impurity concentration of the semiconductor layer 335, it is made possible to obtain a steep subthreshold characteristic even when the semiconductor layer 335 is made thicker insofar as the short channel effect is suppressed and to reduce variations in transistor characteristics. This allows improvement of the manufacturing yield, reducing the cost.

What is claimed is:

1. A semiconductor device comprising;
a semiconductor layer formed on a semiconductor substrate by epitaxial growth;
a first embedded insulating layer embedded in a first region between the semiconductor substrate and the substrate layer; and
a second embedded insulating layer embedded in a second region between the semiconductor substrate and the semiconductor layer,
wherein the first embedded insulating layer and the second embedded insulating layer are mutually different in at least either of effective work function and fixed charge amount.

2. The semiconductor device according to claim 1, wherein the first embedded insulating layer or the second the embedded insulating layer consists of a silicon nitride film, a silicon oxide film containing Al, Hf oxide containing Al, Zr oxide containing Al, a silicon oxide film not containing Al, Hf oxide not containing Al, or Zr oxide not containing Al.

3. A semiconductor device comprising:
a semiconductor layer formed on a first insulating layer and a second insulating layer;
a first back gate electrode disposed below the semiconductor layer via the first insulating layer;
a second back gate electrode disposed below the semiconductor layer via the second insulating layer;
a first gate electrode formed on the semiconductor layer on the first insulating layer; and
a second gate electrode formed on the semiconductor layer on the second insulating layer,
wherein the first and second insulating layers are mutually different in at least either one of effective work function and fixed charge amount.

4. The semiconductor device according to claim 3, wherein the first or second insulating layer consists of a silicon nitride film, a silicon oxide film containing Al, Hf oxide containing Al, Zr oxide containing Al, a silicon oxide film not containing Al, Hf oxide not containing Al, or Zr oxide not containing Al.

5. The semiconductor device according to claim 3, further comprising:
a wiring layer that electrically connects the first and second gate electrodes to the first and second back gate electrodes, respectively.

6. A method of manufacturing a semiconductor device, comprising:
forming a first semiconductor layer on a semiconductor substrate;
forming a second semiconductor layer, which has a smaller etching rate than the first semiconductor layer, on the first semiconductor layer;
forming a first exposing section that exposes the semiconductor substrate by penetrating the first and second semiconductor layers and divides the first and second semiconductor layers into first and second regions;
forming a supporter that supports the second semiconductor layer above the semiconductor substrate via the first exposing section;
forming a second exposing section that exposes a part of the first semiconductor layer in the first region from the second semiconductor layer;
forming below the second semiconductor layer a first cavity, in which the first semiconductor layer in the first region is eliminated, by selectively etching the first semiconductor layer in the first region via the second exposing section;
forming a first embedded insulating layer in such a manner that the first embedded insulating layer is embedded in the first cavity;
forming a third exposing section that exposes a part of the first semiconductor layer in the second region from the second semiconductor layer;
forming below the second semiconductor layer a second cavity, in which the first semiconductor layer in the second region is eliminated, by selectively etching the first semiconductor layer in the second region via the third exposing section; and
forming a second embedded insulating layer in such a manner that the second embedded insulating layer is embedded in the second cavity,
wherein the first and second embedded insulating layers are mutually different in at least either one of effective work function and fixed charge amount.

7. A method of manufacturing a semiconductor device, comprising:
forming a first semiconductor layer on a semiconductor substrate;
forming a second semiconductor layer, which has a smaller etching rate than the first semiconductor layer, on the first semiconductor layer;
forming a third semiconductor layer, which has the same composition as the first semiconductor layer, on the second semiconductor layer;
forming a fourth semiconductor layer, which has the same composition as the second semiconductor layer, on the third semiconductor layer;
forming a first exposing section that exposes the semiconductor substrate by penetrating the first to fourth semiconductor layers and divides the first to fourth semiconductor layers into first and second regions;
forming a supporter that supports the second and fourth semiconductor layers above the semiconductor substrate via the first exposing section;
forming a second exposing section that exposes at least parts of the first and third semiconductor layers in the first region from the second and fourth semiconductor layers;
forming first and second cavities, in which the first and third semiconductor layers in the first region are respectively eliminated, by selectively etching the first and third semiconductor layers via the second exposing section;
forming a first embedded insulating layer in such a manner that the first embedded insulating layer is embedded in each of the first and second cavities;
forming a third exposing section that exposes at least parts of the first and third semiconductor layers in the second region from the second and fourth semiconductor layers;
forming third and fourth cavities, in which the first and third semiconductor layers in the second region are respectively eliminated, by selectively etching the first and third semiconductor layers via the third exposing section; and
forming a second embedded insulating layer in such a manner that the second embedded insulating layer is embedded in each of the third and fourth cavities,
wherein the first and second embedded insulating layers are mutually different in at least either one of effective work function and fixed charge amount.

8. The method of manufacturing a semiconductor device according to claim 7, further comprising:
cleaning backs of the second and fourth semiconductor layers with an ammonia-hydrogen peroxide solution including Al before forming the first or second embedded insulating layer.

9. The method of manufacturing a semiconductor device according to claim 7, further comprising:
cleaning backs of the second and fourth semiconductor layers with a hydrofluoric acid including Al before forming the first or second embedded insulating layer.

10. The method of manufacturing a semiconductor device according to claim 7, wherein the semiconductor substrate and the second and fourth semiconductor layers are each single-crystal Si, and the first and third semiconductor layers are each single-crystal SiGe.

11. A semiconductor device comprising:
a semiconductor layer formed on a semiconductor substrate by epitaxial growth;
an embedded insulating layer that is embedded between the semiconductor substrate and the semiconductor layer;
a gate electrode formed on the semiconductor layer via a gate insulating film; and
source/drain layers formed in the semiconductor layer and each disposed on a side of the gate electrode,
wherein the embedded insulating layer and the gate insulating film are mutually different in at least either one of effective work function and fixed charge amount.

12. The semiconductor device according to claim 11, wherein the gate insulating film consists of a silicon oxide film or a silicon oxide nitride film, and the embedded insulating layer consists of a silicon nitride film, a silicon oxide film containing Al, Hf oxide containing Al, Zr oxide containing Al, Hf oxide not containing Al, or Zr oxide not containing Al.

13. A semiconductor device comprising:
a semiconductor layer formed on an insulating layer;
a back gate electrode disposed below the semiconductor layer via the insulating layer;
a gate electrode formed on the semiconductor layer; and
gate/drain layers formed in the semiconductor layer and each disposed on a side of the gate electrode,
wherein the insulating layer and the gate insulating film are mutually different in at least either one of effective work function and fixed charge amount.

14. The semiconductor device according to claim 13, wherein the gate insulating layer consists of a silicon oxide film or a silicon oxide nitride film, and the embedded insulating layer consists of a silicon nitride film, a silicon oxide film containing Al, Hf oxide containing Al, Zr oxide containing Al, Hf oxide not containing Al, or Zr oxide not containing Al.

15. The semiconductor device according to claim 13, further comprising:
a wiring layer that electrically connects the gate electrode to the back gate electrode.

16. A method of manufacturing a semiconductor device, comprising:
forming a first semiconductor layer on a semiconductor substrate;
forming a second semiconductor layer, which has a smaller etching rate than the first semiconductor layer, on the first semiconductor layer;
forming a first exposing section that exposes the semiconductor substrate be penetrating the first and second semiconductor layers;
forming a supporter that supports the second semiconductor layer above the semiconductor substrate via the first exposing section;
forming a second exposing section that exposes a part of the first semiconductor layer from the second semiconductor layer;
forming below the second semiconductor layer a cavity, in which the first semiconductor layer is eliminated, by selectively etching the first semiconductor layer via the second exposing section;
forming an embedded insulating layer in such a manner that the
embedded insulating layer is embedded in the cavity;
forming a gate insulating film on a surface of the second semiconductor layer; and
forming a gate electrode via the gate insulating film in such a manner that the gate electrode is disposed on the second semiconductor layer,
wherein the embedded insulating layer and the gate insulating film are mutually different in at least either one of effective work function and fixed charge amount.

17. A method of manufacturing a semiconductor device, comprising:
forming a first semiconductor layer on a semiconductor substrate;
forming a second semiconductor layer, which has a smaller etching rate than the first semiconductor layer, on the first semiconductor layer;
forming a first exposing section that exposes the semiconductor substrate by penetrating the first and second semiconductor layers;
forming a supporter that supports the second semiconductor layer above the semiconductor substrate via the first exposing section;
forming a second exposing section that exposes a part of the first semiconductor layer from the second semiconductor layer;
forming below the second semiconductor layer a cavity, in which the first semiconductor layer is eliminated, by selectively etching the first semiconductor layer via the second exposing section;
forming an insulating film in top and bottom portions of the cavity;
forming an embedded back gate electrode in such a manner that the embedded back gate electrode is embedded in the cavity so that top and bottom surfaces of the embedded back gate electrode are interposed between the insulating films;
forming a gate insulating film on a surface of the second semiconductor layer; and
forming a gate electrode via the gate insulating film in such a manner that the gate electrode is disposed on the second semiconductor layer,
wherein the insulating layer and the gate insulating film are mutually different in at least either one of effective work function and fixed charge amount.

18. The method of manufacturing a semiconductor device according to claim 17, further comprising:
cleaning backs of the second and fourth semiconductor layers with an ammonia-hydrogen peroxide solution including Al before forming an insulating layer in the top and bottom portions of the cavity.

19. The method of manufacturing a semiconductor device according to claim 17, further comprising:
cleaning backs of the second and fourth semiconductor layers with a hydrofluoric acid before forming the embedded insulating layer.

20. A method of manufacturing a semiconductor device, comprising:
forming a first semiconductor layer on a semiconductor substrate;
forming a second semiconductor layer, which has a smaller etching rate than the first semiconductor layer, on the first semiconductor layer;
forming a third semiconductor layer, which has the same composition as the first semiconductor layer, on the second semiconductor layer;
forming a fourth semiconductor layer, which has the same composition as the second semiconductor layer, on the third semiconductor layer;
forming a first exposing section that exposes the semiconductor substrate by penetrating the first to fourth semiconductor layers;
forming in the first exposing section a supporter that supports the second and fourth semiconductor layers above the semiconductor substrate;
forming a second exposing section that exposes at least parts of the first and third semiconductor layers from, in which the supporter is formed, from the second and fourth semiconductor layers;
forming first and second cavities, in which the first and third semiconductor layers are respectively eliminated, by selectively etching the first and third semiconductor layers via the second exposing section;
forming an embedded insulating layer in such a manner that the embedded insulating layer is embedded in each of the first and second cavities;
forming a gate insulating film on a surface of the fourth semiconductor layer; and
forming a gate electrode via the gate insulating film in such a manner that the gate electrode is disposed on the fourth semiconductor layer,
wherein the embedded insulating layer and the gate insulating film are mutually different in at least either one of effective work function and fixed charge amount.

21. The method of manufacturing a semiconductor device according to claim 20, further comprising:
cleaning backs of the second and fourth semiconductor layers with an ammonia-hydrogen peroxide solution including Al before forming the embedded insulating layer.

22. The method of manufacturing a semiconductor device according to claim 20, further comprising:
cleaning backs of the second and fourth semiconductor layers with a hydrofluoric acid before forming the embedded insulating layer.

23. The method of manufacturing a semiconductor device according to claim 16, wherein the semiconductor substrate and the second semiconductor layer are each single-crystal Si, and the first semiconductor layer is single-crystal SiGe.

24. The method of manufacturing a semiconductor device according to claim 16, wherein the semiconductor substrate and the second and fourth semiconductor layers are each single-crystal Si, and the first and third semiconductor layers are each single-crystal SiGe.
